(19) United States
(12) Patent Application Publication
(10) Pub. No.: US 2022/0399464 A1
(43) Pub. Date: Dec. 15, 2022

(54) THIN FILM TRANSISTOR SUBSTRATE AND DISPLAY DEVICE COMPRISING THE SAME

(71) Applicant: LG DISPLAY CO., LTD., SEOUL (KR)

(72) Inventors: Younghyun KO, Paju-si (KR); SeungChan CHOI, Paju-si (KR); Min-Gu KANG, Paju-si (KR); Jaeman JANG, Paju-si (KR)

(73) Assignee: LG DISPLAY CO., LTD., SEOUL (KR)

(21) Appl. No.: 17/751,975

(22) Filed: May 24, 2022

(30) Foreign Application Priority Data
Jun. 10, 2021 (KR) 10-2021-0075690

(51) Int. Cl. H01L 29/786; H01L 27/32

(52) U.S. Cl. CPC H01L 29/78618; H01L 29/78696; H01L 29/78633; H01L 29/7869; H01L 27/3244

(57) ABSTRACT

A thin film transistor substrate is provided, which comprises a substrate, a first thin film transistor on the substrate, and a second thin film transistor on the substrate, wherein the first thin film transistor includes a first active layer having a first channel portion, a first gate insulating layer on the first active layer, a first gate electrode on the first gate insulating layer, a first source electrode connected to the first active layer, and a first drain electrode spaced apart from the first source electrode and connected to the first active layer, the second thin film transistor includes a conductive material layer on the substrate, a first buffer layer on the conductive material layer, a second active layer having a second channel portion on the first buffer layer, a second gate insulating layer on the second active layer, a second gate electrode on the second gate insulating layer, a second source electrode connected to the second active layer, and a second drain electrode spaced apart from the second source electrode and connected to the second active layer, and the conductive material layer is connected to the second source electrode and overlaps the second channel portion. Also, a display device comprising the thin film transistor substrate is provided.

### CROSS-REFERENCE TO RELATED APPLICATION

This application claims the priority of the Korean Patent Application No. 10-2021-0075690 filed on Jun. 10, 2021, which is hereby incorporated by reference in its entirety.

### BACKGROUND

### Field of the Disclosure

The present disclosure relates to a thin film transistor substrate and a display device comprising the same.

### Description of the Background

Transistors are widely used as switching devices or driving devices in the field of electronic devices. In particular, since a thin film transistor can be fabricated on a glass substrate or a plastic substrate, the thin film transistor is widely used as a switching device of a display device such as a liquid crystal display device or an organic light emitting device.

The display device may include, for example, a switching thin film transistor and a driving thin film transistor. Generally, it is advantageous that the switching thin film transistor has a small s-factor to improve on-off characteristics and the driving thin film transistor has a large s-factor for expressing a gray scale.

However, since the thin film transistors generally have a small s-factor to make sure of on-off characteristics, it is difficult to express a gray scale when the thin film transistors are applied to the driving thin film transistor of the display device.

Therefore, the thin film transistor having a large s-factor is required to easily express a gray scale by being applied to the driving thin film transistor of the display device.

### SUMMARY

The present disclosure has been made in view of the above problems and is to provide a thin film transistor substrate comprising a thin film transistor having a large s-factor.

More specifically, the present disclosure is to provide a thin film transistor designed to have a large s-factor by including a conductive material layer disposed between a substrate and an active layer and connected with a source electrode, and a thin film transistor substrate comprising the thin film transistor.

The present disclosure is also to provide a thin film transistor substrate that includes a first thin film transistor having a relatively small s-factor and a second thin film transistor having a relatively large s-factor.

Further, the present disclosure is to provide a display device having an excellent gray scale expression capability by including a driving thin film transistor having a large s-factor.

In addition to the above descriptions, features of the present disclosure will be clearly understood by those skilled in the art from the following description of the present disclosure.

In accordance with an aspect of the present disclosure, the above and other features can be accomplished by the provision of a thin film transistor substrate comprising a substrate, a first thin film transistor on the substrate, and a second thin film transistor on the substrate, wherein the first thin film transistor includes a first active layer having a first channel portion, a first gate insulating layer on the first active layer, a first gate electrode on the first gate insulating layer, a first source electrode connected to the first active layer, and a first drain electrode spaced apart from the first source electrode and connected to the first active layer, the second thin film transistor includes a conductive material layer on the substrate, a first buffer layer on the conductive material layer, a second active layer having a second channel portion on the first buffer layer, a second gate insulating layer on the second active layer, a second gate electrode on the second gate insulating layer, a second source electrode connected to the second active layer, and a second drain electrode spaced apart from the second source electrode and connected to the second active layer, wherein the conductive material layer is connected to the second source electrode and overlaps the second channel portion.

The second thin film transistor has an s-factor larger than that of the first thin film transistor.

The conductive material layer may have a light shielding characteristic.

The conductive material layer does not overlap the first channel portion.

The first buffer layer may be disposed between the substrate and the first active layer and between the substrate and the second active layer.

The first buffer layer may have a thickness of 50 nm to 300 nm.

The second gate insulating layer may have a thickness of 0.75 times to 5 times that of the first buffer layer.

The first buffer layer may include a hydrogen blocking layer on the conductive material layer, and a buffer insulating layer on the hydrogen blocking layer.

The hydrogen blocking layer may include silicon nitride (SiNx).

The hydrogen blocking layer may have a thickness of 10 nm to 100 nm.

The first gate insulating layer and the second gate insulating layer have the same thickness.

The first gate insulating layer and the second gate insulating layer may be integrally formed.

At least one of the first gate insulating layer or the second gate insulating layer may include a gate insulator, and an interface layer on the gate insulator, and the interface layer may be disposed to be closer to any one of the first channel portion and the second channel portion than the gate insulator.

The interface layer may be formed by a metal organic chemical vapor deposition (MOCVD) method.

The interface layer may include at least one of silicon oxide (SiOx), silicon nitride (SiNx) or metal oxide.

The interface layer may include SiO₂.

The interface layer may have a thickness of 1 nm to 10 nm.

The thin film transistor substrate may further comprise a first pad layer disposed between the substrate and the first buffer layer and overlapped with the first channel portion.

The first pad layer does not overlap the second channel portion.

The first pad layer may have conductivity and light shielding characteristics.

The first pad layer may be connected to the first gate electrode.

The thin film transistor substrate may further comprise a second buffer layer disposed between the substrate and the first buffer layer.

The conductive material layer is disposed between the first buffer layer and the second buffer layer.

The first pad layer may be disposed between the substrate and the second buffer layer.

The first pad layer may be connected to the first source electrode.

The first pad layer may be connected to the first gate electrode.

The first pad layer may be disposed between the first buffer layer and the second buffer layer.

The first pad layer may be connected to the first gate electrode.

At least one of the first active layer or the second active layer may include an oxide semiconductor material.

The oxide semiconductor material may include at least one of IZO(InZnO)-based, IGO(InGaO)-based, ITO(InSnO)-based, IGZO(InGaZnO)-based, IGZTO (InGaZnSnO)-based, GZTO(GaZnSnO)-based, GZO(GaZnO)-based, ITZO(InSnZnO)-based or FIZO(FeInZnO)-based oxide semiconductor material.

At least one of the first active layer or the second active layer may include a first oxide semiconductor layer, and a second oxide semiconductor layer on the first oxide semiconductor layer.

At least one of the first active layer or the second active layer may further include a third oxide semiconductor layer on the second oxide semiconductor layer.

In accordance with another aspect of the present disclosure, the above and other features can be accomplished by the provision of a display device comprising the thin film transistor substrate and a display element connected to the second thin film transistor of the thin film transistor substrate.

The display element may include an organic light emitting diode.

### BRIEF DESCRIPTION OF THE DRAWINGS

The above features and other advantages of the present disclosure will be more clearly understood from the following detailed description taken in conjunction with the accompanying drawings, in which:

FIGS. 1A and 1B are cross-sectional views illustrating a thin film transistor substrate according to one aspect of the present disclosure;

FIGS. 2A and 2B are cross-sectional views illustrating a thin film transistor substrate according to another aspect of the present disclosure;

FIGS. 3A and 3B are cross-sectional views illustrating a thin film transistor substrate according to still another aspect of the present disclosure;

FIG. 4 is a cross-sectional view illustrating a thin film transistor substrate according to further still another aspect of the present disclosure;

FIG. 5 is a cross-sectional view illustrating a thin film transistor substrate according to further still another aspect of the present disclosure;

FIG. 6 is a cross-sectional view illustrating a thin film transistor substrate according to further still another aspect of the present disclosure;

FIG. 7 is a cross-sectional view illustrating a thin film transistor substrate according to further still another aspect of the present disclosure;

FIGS. 8A to 8E are graphs illustrating threshold voltages for thin film transistors;

FIGS. 9A and 9B are graphs illustrating threshold voltages for thin film transistors;

FIG. 10 is a graph for a relation between an s-factor and a thickness ratio of a first buffer layer and a gate insulating layer;

FIGS. 11A and 11B are schematic views illustrating an effective gate voltage of a first thin film transistor according to one aspect of the present disclosure;

FIGS. 12A and 12B are schematic views illustrating an effective gate voltage of a second thin film transistor according to one aspect of the present disclosure;

FIGS. 13A and 13B are schematic views illustrating an effective gate voltage of a first thin film transistor according to another aspect of the present disclosure;

FIG. 14 is a schematic view illustrating a display device according to another aspect of the present disclosure;

FIG. 15 is a circuit view illustrating any one pixel of FIG. 14;

FIG. 16 is a plan view illustrating the pixel of FIG. 15;

FIG. 17 is a cross-sectional view taken along line I-I′ of FIG. 16;

FIG. 18 is a plan view illustrating any one pixel of a display device according to another aspect of the present disclosure;

FIG. 19 is a cross-sectional view taken along line II-II′ of FIG. 18;

FIG. 20 is a cross-sectional view taken along line III-III′ of FIG. 18;

FIG. 21 is a plan view illustrating any one pixel of a display device according to still another aspect of the present disclosure;

FIG. 22 is a cross-sectional view taken along line IV-IV′ of FIG. 21;

FIG. 23 is a cross-sectional view taken along line V-V′ of FIG. 21;

FIG. 24 is a plan view illustrating any one pixel of a display device according to further still another aspect of the present disclosure;

FIG. 25 is a cross-sectional view taken along line VI-VI′ of FIG. 24;

FIG. 26 is a cross-sectional view taken along line VII-VII′ of FIG. 24;

FIG. 27 is a circuit view illustrating any one pixel of a display device according to further still another aspect of the present disclosure; and

FIG. 28 is a circuit view illustrating any one pixel of a display device according to further still another aspect of the present disclosure.

### DETAILED DESCRIPTION

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing aspects of the present disclosure are merely an example, and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when the position relationship is described as ‘upon˜’, ‘above˜’, ‘below˜’, and ‘next to˜’, one or more portions may be arranged between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the figures. It will be understood that these terms are intended to encompass different orientations of the device in addition to the orientation depicted in the figures. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,”“subsequent,”“next,” and “before,” a case which is not continuous may be included, unless “just” or “direct” is used.

It will be understood that, although the terms “first”, “second”, etc. may be used herein to describe various elements, these elements should not be limited by these terms. These terms are only used to partition one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

In the drawings, the same or similar elements are denoted by the same reference numerals even though they are depicted in different drawings.

In the aspects of the present disclosure, a source electrode and a drain electrode are distinguished from each other, for convenience of description. However, the source electrode and the drain electrode may be used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In the aspects of the present disclosure, a source electrode and a drain electrode are not limited as described above. A source region in any one aspect of the present disclosure may be a source electrode, a drain region in any one aspect of the present disclosure may be a drain electrode. A source region in any one aspect of the present disclosure may be a drain electrode, a drain region in any one aspect of the present disclosure may be a source electrode.

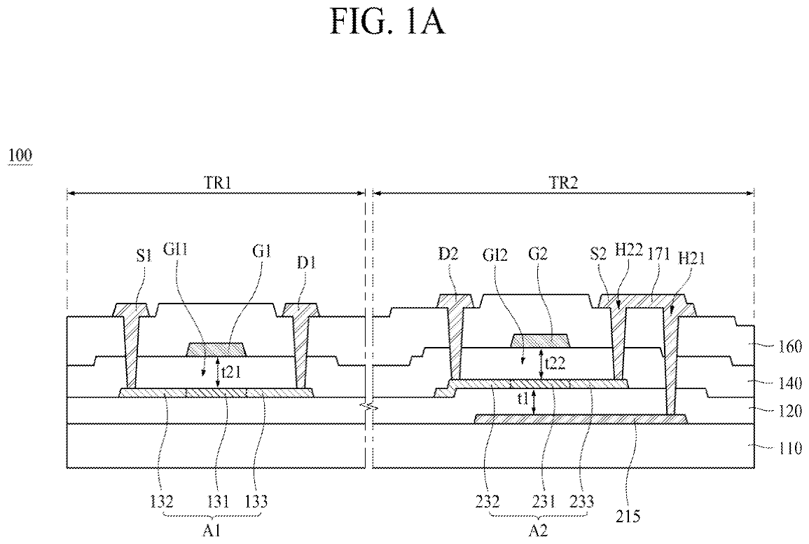

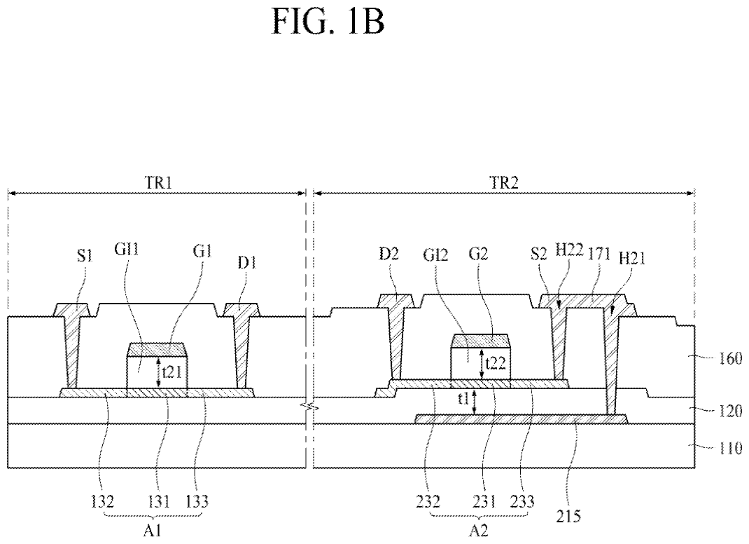

FIGS. 1A and 1B are cross-sectional views illustrating a thin film transistor substrate 100 according to one aspect of the present disclosure.

The thin film transistor substrate 100 according to one aspect of the present disclosure includes a substrate 110, a first thin film transistor TR1 on the substrate 110 and a second thin film transistor TR2 on the substrate 110.

The first thin film transistor TR1 includes a first active layer A1 having a first channel portion 131, a first gate insulating layer GI1 on the first active layer A1, a first gate electrode G1 on the first gate insulating layer GI1, a first source electrode S1 connected to the first active layer A1, and a first drain electrode D1 spaced apart from the first source electrode S1 and connected to the first active layer A1.

The second thin film transistor TR2 includes a conductive material layer 215 on the substrate 110, a first buffer layer 120 on the conductive material layer 215, a second active layer A2 having a second channel portion 231 on the first buffer layer 120, a second gate insulating layer GI2 on the second active layer A2, a second gate electrode G2 on the second gate insulating layer GI2, a second source electrode S2 connected to the second active layer A2, and a second drain electrode D2 spaced apart from the second source electrode S2 and connected to the second active layer A2.

In the second thin film transistor TR2, the conductive material layer 215 is connected to the second source electrode S2 and overlaps the second channel portion 231.

The second thin film transistor TR2 having a conductive material layer 215 overlapped with the second channel portion 231 and connected to the second source electrode S2 has an s-factor larger than that of the first thin film transistor TR1. The second thin film transistor TR2 may be used as a driving thin film transistor of the display device.

Hereinafter, the thin film transistor substrate 100 according to one aspect of the present disclosure will be described in more detail with reference to FIGS. 1A and 1B.

Glass or plastic may be used as the substrate 110. A transparent plastic, e.g., polyimide, which has a flexible property may be used as the plastic. When polyimide is used as the substrate 110, a heat resistant polyimide that can withstand high temperatures may be used when the polyimide is formed on the substrate 110.

The conductive material layer 215 is disposed on the substrate 110. The conductive material layer 215 overlaps the second channel portion 231.

The conductive material layer 215 has electrical conductivity. The conductive material layer 215 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), titanium (Ti) or iron (Fe). The conductive material layer 215 may have a multi-layered structure that includes at least two conductive material layers having their respective physical properties different from each other.

According to one aspect of the present disclosure, the conductive material layer 215 is connected to the second source electrode S2. Therefore, the same voltage as that of the second source electrode S2 may be applied to the conductive material layer 215.

According to one aspect of the present disclosure, the conductive material layer 215 overlaps the second channel portion 231. When the same voltage as that of the second source electrode S2 is applied to the conductive material layer 215, the conductive material layer 215 may electrically affect the second channel portion 231. Due to the electrical influence by the conductive material layer 215, an influence of an electric field applied to the second channel portion 231 by the second gate electrode G2 may be reduced.

According to one aspect of the present disclosure, the conductive material layer 215 does not overlap the first channel portion 131. Therefore, the voltage applied to the conductive material layer 215 does not directly affect the first channel portion 131 and the first active layer A1.

According to one aspect of the present disclosure, the conductive material layer 215 may have a light shielding characteristic. Thus, the conductive material layer 215 may serve as a light shielding layer. The conductive material layer 215 may shield light incident on the substrate 110 to protect the second channel portion 231 and the second active layer A2.

The first buffer layer 120 is disposed on the conductive material layer 215. The first buffer layer 120 may include at least one of silicon oxide, silicon nitride or metal-based oxide. According to one aspect of the present disclosure, the first buffer layer 120 may include at least one of silicon oxide or silicon nitride. The first buffer layer 120 may have a single layered structure, or may have a multi-layered structure.

The first buffer layer 120 protects the first active layer A1 and the second active layer A2. In addition, a surface of an upper portion of the substrate 110 may be uniformly maintained by the first buffer layer 120.

The first buffer layer 120 allows the conductive material layer 215 and the second channel portion 231 to be spaced apart from each other.

According to one aspect of the present disclosure, the first buffer layer 120 may be disposed between the substrate 110 and the first active layer A1 and between the substrate 110 and the second active layer A2. Referring to FIGS. 1A and 1B, the first buffer layer 120 may be disposed on an entire surface on the substrate 110. The conductive material layer 215 and the second channel portion 231 are spaced apart from each other and insulated from each other by the first buffer layer 120.

According to one aspect of the present disclosure, the first buffer layer 120 may have a thickness t1 of 50 nm to 300 nm. According to one aspect of the present disclosure, the thickness t1 of the first buffer layer 120 is defined as a distance between an upper surface of the conductive material layer 215 and a lower surface of the second channel portion 231.

When the thickness t1 of the first buffer layer 120 is less than 50 nm, the first buffer layer 120 may fail to prevent hydrogen (H) or oxygen (O) from being permeated into the first and second thin film transistors TR1 and TR2, whereby functions of the first thin film transistor TR1 and the second thin film transistor TR2 may be deteriorated. For example, when the thickness t1 of the first buffer layer 120 is less than 50 nm, the first channel portion 131 and the second channel portion 231 are conductorized by hydrogen (H) permeated from the outside of the first thin film transistor TR1 and the second thin film transistor TR2, whereby transistor functions of the first thin film transistor TR1 and the second thin film transistor TR2 may be lost.

When the thickness t1 of the first buffer layer 120 exceeds 300 nm, a distance between the conductive material layer 215 and the second channel portion 231 may be increased, whereby capacitance Cap between the conductive material layer 215 and the second channel portion 231 may become very small. As a result, even though the same voltage as that of the second source electrode S2 is applied to the conductive material layer 215, the electrical influence of the conductive material layer 215 on the second channel portion 231 may be very small. The effect of reducing the influence of the electric field applied to the second channel portion 231 by the second gate electrode G2 may almost not occur when the electrical influence of the conductive material layer 215 on the second channel portion 231 is reduced.

The first active layer A1 and the second active layer A2 are disposed on the first buffer layer 120.

The first active layer A1 and the second active layer A2 may be formed by a semiconductor material. The first active layer A1 of the first thin film transistor TR1 may have a composition the same as or different from that of the second active layer A2 of the second thin film transistor TR2. The first active layer A1 and the second active layer A2 may include, for example, one of an amorphous silicon semiconductor material, a polycrystalline silicon semiconductor material and an oxide semiconductor.

According to one aspect of the present disclosure, at least one of the first active layer A1 or the second active layer A2 may include an oxide semiconductor material. The oxide semiconductor material may include, for example, at least one of IZO(InZnO)-based, IGO(InGaO)-based, ITO(InSnO)-based, IGZO(InGaZnO)-based, IGZTO (InGaZnSnO)-based, GZTO(GaZnSnO)-based, GZO(GaZnO)-based, ITZO(InSnZnO)-based or FIZO(FeInZnO)-based oxide semiconductor material, but one aspect of the present disclosure is not limited thereto. The first active layer A1 and the second active layer A2 may be made of other oxide semiconductor materials known in the art.

The first active layer A1 may include a first channel portion 131, a first conductorization portion 132 and a second conductorization portion 133. The first channel portion 131 overlaps the first gate electrode G1. The first conductorization portion 132 and the second conductorization portion 133 of the first active layer A1 do not overlap the first gate electrode G1. The first conductorization portion 132 and the second conductorization portion 133 may be formed by selective conductorization of the semiconductor material.

According to one aspect of the present disclosure, the first conductorization portion 132 of the first active layer A1 may be a source area, and the second conductorization portion 133 may be a drain area. According to one aspect of the present disclosure, the first conductorization portion 132 may be referred to as a source electrode and the second conductorization portion 133 may be referred to as a drain electrode, but one aspect of the present disclosure is not limited thereto. The first conductorization portion 132 may be a drain area and the second conductorization portion 133 may be a source area. In addition, the first conductorization portion 132 may be referred to as a drain electrode, and the second conductorization portion 133 may be referred to as a source electrode.

The second active layer A2 may include a second channel portion 231, a first conductorization portion 232 and a second conductorization portion 233. The second channel portion 231 overlaps the second gate electrode G2. The first conductorization portion 232 and the second conductorization portion 233 of the second active layer A2 do not overlap the second gate electrode G2. The first conductorization portion 232 and the second conductorization portion 233 may be formed by selective conductorization of the semiconductor material.

According to one aspect of the present disclosure, the first conductorization portion 232 of the second active layer A2 may be a source area and the second conductorization portion 233 may be a drain area. According to one aspect of the present disclosure, the first conductorization portion 232 may be referred to as a source electrode and the second conductorization portion 233 may be referred to as a drain electrode, but one aspect of the present disclosure is not limited thereto. The first conductorization portion 232 may be a drain area and the second conductorization portion 233 may be a source area. In addition, the first conductorization portion 232 may be referred to as a drain electrode and the second conductorization portion 233 may be referred to as a source electrode.

The first gate insulating layer GI1 is disposed on the first active layer A1, and the second gate insulating layer GI2 is disposed on the second active layer A2. In more detail, the first gate insulating layer GI1 is disposed on the first channel portion 131, and the second gate insulating layer GI2 is disposed on the second channel portion 231. The first gate insulating layer GI1 and the second gate insulating layer GI2 may be formed in separate patterns so as to be distinguished from each other (FIG. 1B), and may be integrally formed without being distinguished from each other (FIG. 1A).

Each of the first gate insulating layer GI1 and the second gate insulating layer GI2 may include at least one of silicon oxide, silicon nitride or metal-based oxide. Each of the first gate insulating layer GI1 and the second gate insulating layer GI2 may have a single layered structure, or may have a multi-layered structure.

The first gate insulating layer GI1 of the first thin film transistor TR1 and the second gate insulating layer GI2 of the second thin film transistor TR2 may have the same composition, and may be formed by the same process. According to one aspect of the present disclosure, a thickness t21 of the first gate insulating layer GI1 and a thickness t22 of the second gate insulating layer GI2 may be the same as each other.

Referring to FIG. 1A, the first gate insulating layer GI1 and the second gate insulating layer GI2 may be integrally formed on the entire surface of the substrate 110 without being patterned. Since the first gate insulating layer GI1 and the second gate insulating layer GI2 of FIG. 1A are integrally formed, the first gate insulating layer GI1 and the second gate insulating layer GI2 may be collectively referred to as a gate insulating layer 140.

Referring to FIG. 1B, the first gate insulating layer GI1 and the second gate insulating layer GI2 may be separately formed by being patterned. In the thin film transistor shown in FIG. 1B, the thickness t21 of the first gate insulating layer GI1 and the thickness t22 of the second gate insulating layer GI2 may be the same as each other (t21=t22).

The first gate insulating layer GI1 and the second gate insulating layer GI2 protect the first channel portion 131 and the second channel portion 231, respectively.

The first gate electrode G1 of the first thin film transistor TR1 is disposed on the first gate insulating layer GI1. The first gate electrode G1 overlaps the first channel portion 131 of the first active layer A1.

The second gate electrode G2 of the second thin film transistor TR2 is disposed on the second gate insulating layer GI2. The second gate electrode G2 overlaps the second channel portion 231 of the second active layer A2.

Each of the first gate electrode G1 and the second gate electrode G2 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd) or titanium (Ti). The first gate electrode G1 and the second gate electrode G2 may have a multi-layered structure that includes at least two conductive material layers having their respective physical properties different from each other.

An interlayer insulating layer 160 is disposed on the first gate electrode G1 and the second gate electrode G2. The interlayer insulating layer 160 is an insulating layer made of an insulating material. The interlayer insulating layer 160 may be made of an organic material, or may be made of an inorganic material, or may be made of a stacked structure of an organic layer and an inorganic layer.

The first source electrode S1, the first drain electrode D1, the second source electrode S2 and the second drain electrode D2 are disposed on the interlayer insulating layer 160.

The first source electrode S1 is connected to the first active layer A1 through a contact hole. The first drain electrode D1 is spaced apart from the first source electrode S1, and is connected to the first active layer A1 through the contact hole.

The second source electrode S2 is connected to the second active layer A2 through the contact hole. The second drain electrode D2 is spaced apart from the second source electrode S2, and is connected to the second active layer A2 through the contact hole.

Each of the first source electrode S1, the first drain electrode D1, the second source electrode S2 and the second drain electrode D2 may include at least one of molybdenum (Mo), aluminum (Al), chromium (Cr), gold (Au), titanium (Ti), nickel (Ni), neodymium (Nd), copper (Cu) or their alloy. Each of the first source electrode S1, the first drain electrode D1, the second source electrode S2 and the second drain electrode D2 may be formed of a single layer made of metal or its alloy, or may be formed of two or more multiple layers.

Referring to FIGS. 1A and 1B, a bridge 171 may be disposed on the interlayer insulating layer 160. The bridge 171 is connected to the second source electrode S2. The bridge 171 may be extended from the second source electrode S2, and a portion of the second source electrode S2 may be the bridge 171.

The bridge 171 is connected to the conductive material layer 215 through a contact hole H21. The contact hole H21 is formed through the interlayer insulating layer 160 and the first buffer layer 120.

The second source electrode S2 and the conductive material layer 215 of the second thin film transistor TR2 may be connected to each other by the bridge 171.

When the first conductorization portion 132 of the first active layer A1 serves as the first source electrode and the second conductorization portion 133 serves as the first drain electrode, the first source electrode S1 and the first drain electrode D1 on the interlayer insulating layer 160 may be omitted.

In addition, when the first conductorization portion 232 of the second active layer A2 serves as the second drain electrode and the second conductorization portion 233 serves as the second source electrode, the second source electrode S2 and the second drain electrode D2 on the interlayer insulating layer 160 may be omitted. In this case, the second source electrode S2 on the interlayer insulating layer 160 may be a portion of the bridge 171.

Referring to FIGS. 1A and 1B, the bridge 171 may connect the second conductorization portion 233 of the second active layer A2 with the conductive material layer 215 through two contact holes H21 and H22. When the second conductorization portion 233 of the second active layer A2 serves as the second drain electrode, the bridge 171 may connect the conductive material layer 215 with the second drain electrode through the two contact holes H21 and H22.

According to one aspect of the present disclosure, the second thin film transistor TR2 having the conductive material layer 215 connected to the second source electrode S2 has an s-factor larger than the first thin film transistor TR1.

Hereinafter, the s-factor will be described in detail.

In a drain-source current graph for gate voltages of the thin film transistors TR1 and TR2, the s-factor (sub-threshold swing) is obtained by an inverse value of a slope of the graph at a period of a threshold voltage Vth. For example, at the period of the threshold voltage Vth of the thin film transistors TR1 and TR2, the s-factor may be used as an index indicating a change level of the drain-source current with respect to the gate voltage.

When the s-factor becomes large, a change rate of a drain-source current I_{DS} for the gate voltage at the period of the threshold voltage Vth becomes slow.

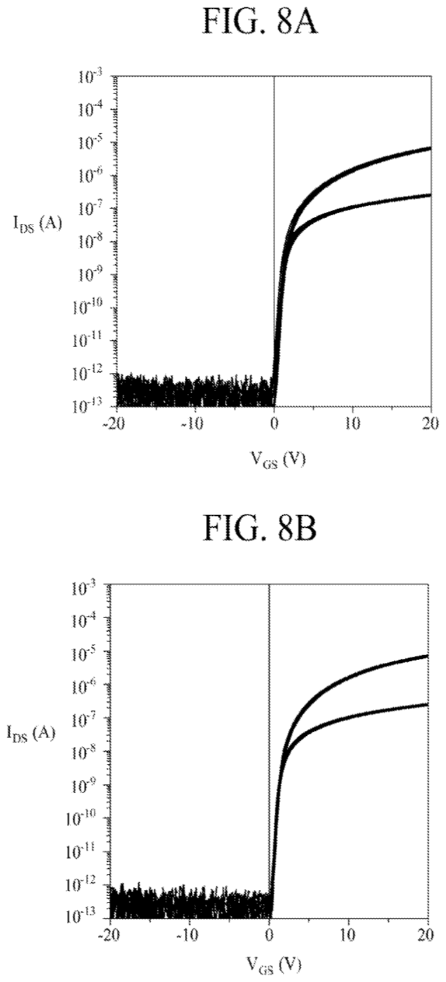

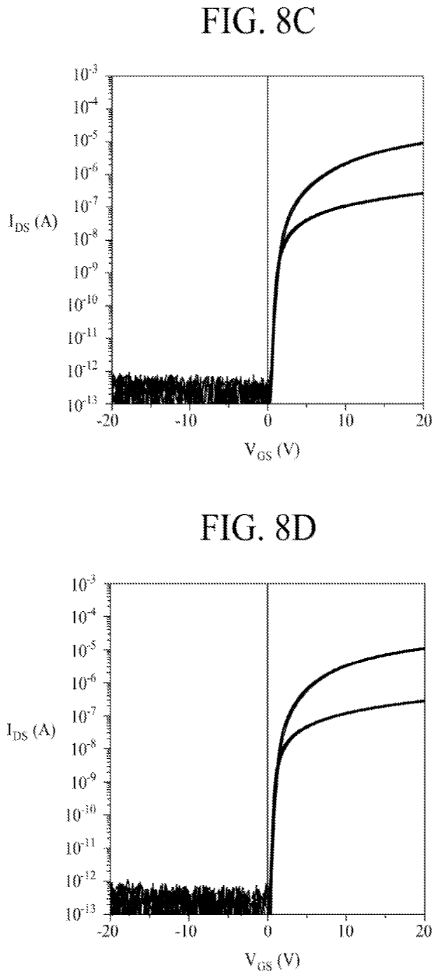

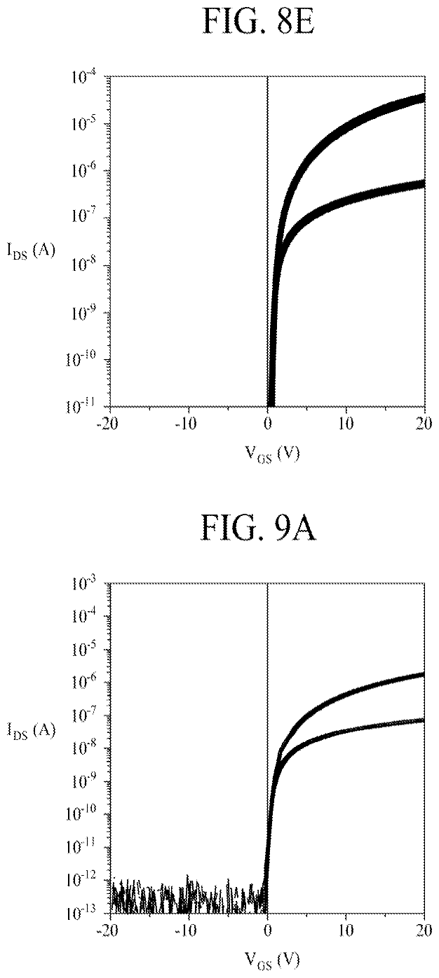

The s-factor may be described, for example, by current change graphs shown in FIGS. 8A to 8E. FIGS. 8A to 8E are graphs illustrating threshold voltages for thin film transistors, respectively. In detail, FIGS. 8A to 8E show a drain-source current I_{DS} for a gate voltage V_{GS}. At the period of the threshold voltage Vth of the graphs shown in FIGS. 8A to 8E, an inverse number in the graph of the drain-source current I_{DS} for the gate voltage V_{GS} is an s-factor. When the slope of the graph is steep, the s-factor is small, and when the slope of the graph is slow, the s-factor is large. When the s-factor is large, a change rate of the drain-source current I_{DS} for the gate voltage at the period of the threshold voltage Vth is slow.

When the s-factor becomes large, since the change rate of the drain-source current I_{DS} for the gate voltage at the period of the threshold voltage Vth becomes slow, it is easy to adjust the magnitude of the drain-source current I_{DS} by adjusting the gate voltage V_{GS}.

In the display device driven by the current, for example, in an organic light emitting display device, a gray scale of a pixel may be controlled by adjusting the magnitude of the drain-source current I_{DS} of the driving thin film transistor. The magnitude of the drain-source current I_{DS} of the driving thin film transistor is determined by the gate voltage. Therefore, in the organic light emitting display device driven by the current, it is easy to adjust the gray scale of the pixel as the s-factor of the driving TFT becomes large.

According to one aspect of the present disclosure, since the conductive material layer 215 overlaps the second channel portion 231, when the same voltage as that of the second source electrode S2 is applied to the conductive material layer 215, the second channel portion 231 may be electrically affected by the conductive material layer 215. Due to the electrical influence by the conductive material layer 215, the influence of the electric field applied to the second channel portion 231 by the second gate electrode G2 may be reduced. As a result, the s-factor of the second thin film transistor TR2 that includes the conductive material layer 215 may be larger than that of the first thin film transistor TR1 that does not include the conductive material layer 215.

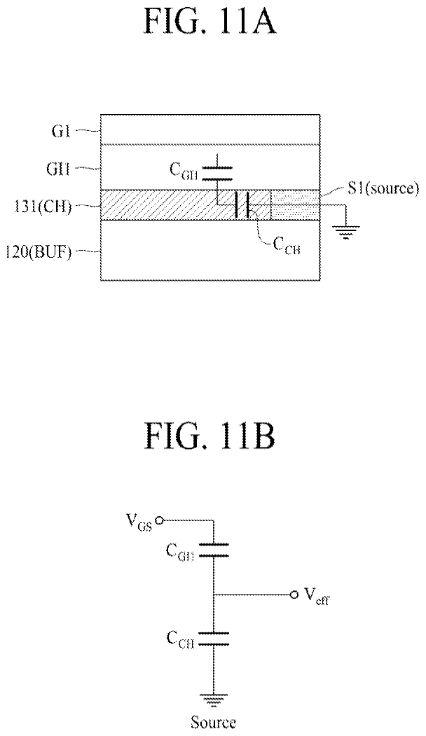

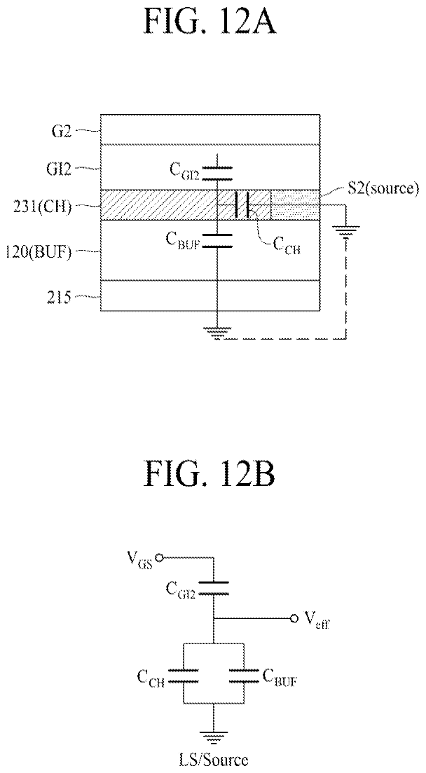

The influence of the conductive material layer 215 on the s-factor of the second thin film transistor TR2 may be described by FIGS. 11A, 11B, 12A and 12B.

FIGS. 11A and 11B are schematic views illustrating an effective gate voltage V_{eff} of the first thin film transistor TR1 according to one aspect of the present disclosure.

FIG. 11A schematically illustrates capacitance Cap that may occur when a gate voltage V_{GS} is applied to the first thin film transistor TR1. The gate voltage V_{GS} is a voltage between the first source electrode S1 and the first gate electrode G1. In FIG. 11A, before the first thin film transistor TR1 is completely turned on, the relation of the capacitance Cap in a voltage near the threshold voltage Vth is schematically illustrated.

As shown in FIG. 11A, when the gate voltage V_{GS} is applied to the first thin film transistor TR1, capacitance C_{GI1} may be formed between the first channel portion 131 of the first active layer A1 and the first gate electrode G1, and capacitance C_{CH} may be formed between the first channel portion 131 and the first source electrode S1.

The relation between the voltage and the capacitance according to FIG. 11A may be expressed as shown in FIG. 11B. Referring to FIG. 11B, due to the capacitance C_{CH} between the first channel portion 131 and the first source electrode S1, the gate voltage V_{GS} applied between the first source electrode S1 and the first gate electrode G1 may not be applied between the first channel portion 131 and the first gate electrode G1. As a result, voltage loss may be generated.

Referring to FIG. 11B, when a voltage applied between the first channel portion 131 and the first gate electrode G1 is referred to as an effective gate voltage V_{eff} during driving of the first thin film transistor TR1, the effective gate voltage V_{eff} may be obtained by the following Equation 1.

V_{eff}=[C_{GI1}/(C_{GI1}+C_{CH})]×V_{GS} [Equation 1]

FIGS. 12A and 12B are schematic views illustrating an effective gate voltage V_{eff} of the second thin film transistor TR2 according to one aspect of the present disclosure.

FIG. 12A schematically illustrates capacitance Cap that may occur when a gate voltage V_{GS} is applied to the second thin film transistor TR2. In FIG. 12A, before the second thin film transistor TR2 is completely turned on, the relation of the capacitance Cap in a voltage near the threshold voltage Vth is schematically illustrated.

As shown in FIG. 12A, when the gate voltage V_{GS} is applied to the second thin film transistor TR2, capacitance C_{GI2} may be formed between the second channel portion 231 of the second active layer A2 and the second gate electrode G2, capacitance C_{CH} may be formed between the second channel portion 231 and the second source electrode S2, and capacitance C_{BUF} may be additionally formed between the second channel portion 231 and the conductive material layer 215. In FIGS. 12A and 12B, since the conductive material layer 215 may serve as a light shielding layer, the conductive material layer 215 may be marked with LS (light shielding layer).

The relation between the voltage and the capacitance Cap according to FIG. 12A may be expressed as shown in FIG. 12B. Referring to FIG. 12B, due to the capacitance C_{CH} between the second channel portion 231 and the second source electrode S2 and the capacitance C_{BUF} between the second channel portion 231 and the conductive material layer 215, the gate voltage V_{GS} applied between the second source electrode S2 and the second gate electrode G2 may not be applied between the second channel portion 231 and the second gate electrode G2. As a result, voltage loss may be generated.

According to one aspect of the present disclosure, the conductive material layer 215 and the second source electrode S2 are electrically connected to each other. As a result, the capacitance C_{BUF} is additionally generated between the second channel portion 231 and the conductive material layer 215, whereby the capacitance Cap of the lower portion of the second channel portion 231, in which voltage loss is generated, is increased (C_{CH}+C_{BUF}). Therefore, referring to FIG. 12B, when a voltage applied between the second channel portion 231 and the second gate electrode G2 is referred to as an effective gate voltage V_{eff} during the driving of the second thin film transistor TR2, the effective gate voltage V_{eff} may be obtained by the following Equation 2.

V_{eff}=[C_{GI2}/(C_{GI2}+C_{CH}+C_{BUF})]×V_{GS} [Equation 2]

Referring to the Equation 2, a denominator portion of the Equation 2 was increased due to the capacitance C_{BUF} between the second channel portion 231 and the conductive material layer 215. Therefore, a decrease in the effective gate voltage V_{eff} is greater than that of the gate voltage V_{GS} actually applied between the second source electrode S2 and the second gate electrode G2. Therefore, when the same voltage is applied, the drain-source current I_{DS} of the second thin film transistor TR2 is smaller than the drain-source current I_{DS} of the first thin film transistor TR1, and the change level of the drain-source current I_{DS} is also small.

In this way, since the change of the drain-source current I_{DS} of the second thin film transistor TR2 is smaller than that of the first thin film transistor TR1, the second thin film transistor TR2 has an s-factor larger than that of the first thin film transistor TR1.

According to one aspect of the present disclosure, the second channel portion 231 and the conductive material layer 215 are spaced apart from each other with the first buffer layer 120 interposed therebetween. Therefore, when the thickness of the first buffer layer 120 is increased, a distance between the conductive material layer 215 and the second channel portion 231 is increased, whereby the capacitance C_{BUF} between the second channel portion 231 and the conductive material layer 215 is reduced. When the capacitance C_{BUF} between the second channel portion 231 and the conductive material layer 215 is reduced, the s-factor of the second thin film transistor TR2 will become smaller.

Thus, in order that the s-factor of the second thin film transistor TR2 has a relatively large value, the first buffer layer 120 may have a thickness of a predetermined value or less. According to one aspect of the present disclosure, the first buffer layer 120 may have a thickness t1 of 300 nm or less. When the thickness t1 of the first buffer layer 120 exceeds 300 nm, the distance between the conductive material layer 215 and the second channel portion 231 may be increased, whereby the capacitance C_{BUF} between the conductive material layer 215 and the second channel portion 231 may become very smaller. As a result, the s-factor of the second thin film transistor TR2 may become small.

As described above, when the thickness t1 of the first buffer layer 120 is less than 50 nm, a function of the first buffer layer 120 that blocks hydrogen (H) or oxygen (O) may be deteriorated, whereby the first channel portion 131 and the second channel portion 231 may be damaged or conductorized.

Therefore, according to one aspect of the present disclosure, the first buffer layer 120 may have a thickness t1 of 50 nm to 300 nm. In more detail, the first buffer layer 120 may have a thickness t1 of 50 nm to 250 nm, may have a thickness t1 of 80 nm to 250 nm, may have a thickness t1 of 80 nm to 200 nm, may have a thickness t1 of 100 nm to 200 nm, or may have a thickness t1 of 120 nm to 300 nm.

Referring to the Equation 2, when the second thin film transistor TR2 is driven, the effective gate voltage V_{eff} is influenced by the capacitance C_{GI2} between the second channel portion 231 and the second gate electrode G2. Further, the capacitance C_{GI2} between the second channel portion 231 and the second gate electrode G2 is affected by the thickness t22 of the second gate insulating layer GI2.

According to one aspect of the present disclosure, the second gate insulating layer GI2 may have a thickness of 0.75 times to 5 times that of the first buffer layer 120 so that the second thin film transistor TR2 has a large s-factor and simultaneously turns on and off a flow of the current. For example, the thickness t1 of the first buffer layer 120 and the thickness t22 of the second gate insulating layer GI2 may satisfy the following Equation 3.

0.75≤t22/t1≤5 [Equation 3]

When the thickness t22 of the second gate insulating layer GI2 is less than 0.75 times the thickness t1 of the first buffer layer 120 (0.75>t22/t1), most of the gate voltage V_{GS} is applied between the second channel portion 231 and the second gate electrode G2 and the influence of the conductive material layer 215 is reduced, whereby the slope of the threshold voltage graph may be increased, and the s-factor of the second thin film transistor TR2 may be reduced.

On the other hand, when the thickness t22 of the second gate insulating layer GI2 exceeds five times the thickness t1 of the first buffer layer 120 (t22/t1>5), the s-factor of the second thin film transistor TR2 may become large excessively. When the s-factor of the second thin film transistor TR2 becomes large excessively, excessive power may be consumed to drive the second thin film transistor TR2.

According to one aspect of the present disclosure, the second gate insulating layer GI2 may have a thickness of 1 to 3.5 times or a thickness of 1.5 to 3 times as compared with the first buffer layer 120.

According to one aspect of the present disclosure, the second thin film transistor TR2 may have an s-factor of 0.28 or more, for example. When the second thin film transistor TR2 has an s-factor of 0.28 or more, the gray scale of the pixel may be easily adjusted.

According to one aspect of the present disclosure, the second thin film transistor TR2 may have an s-factor of 0.3 or more in consideration of easiness in adjustment of the gray scale. When the s-factor of the second thin film transistor TR2 becomes large excessively, power consumption required to drive the second thin film transistor TR2 is increased. In consideration of these features, the second thin film transistor TR2 according to one aspect of the present disclosure may have an s-factor in the range of 0.3 to 0.7. Therefore, the second thin film transistor TR2 may be used as a driving transistor of the display device.

On the other hand, the first thin film transistor TR1 has an s-factor smaller than that of the second thin film transistor TR2. The first thin film transistor TR1 having a small s-factor has excellent switching characteristics. Therefore, the first thin film transistor TR1 may be used as a switching transistor of the display device.

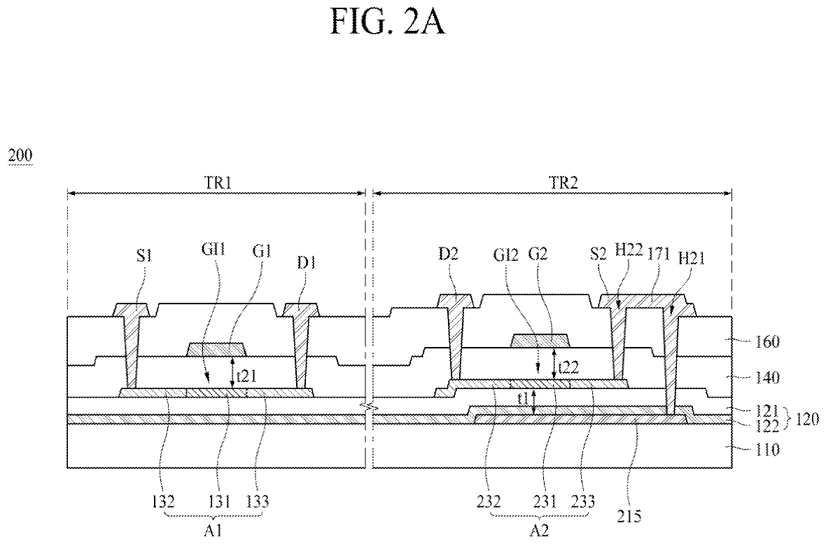

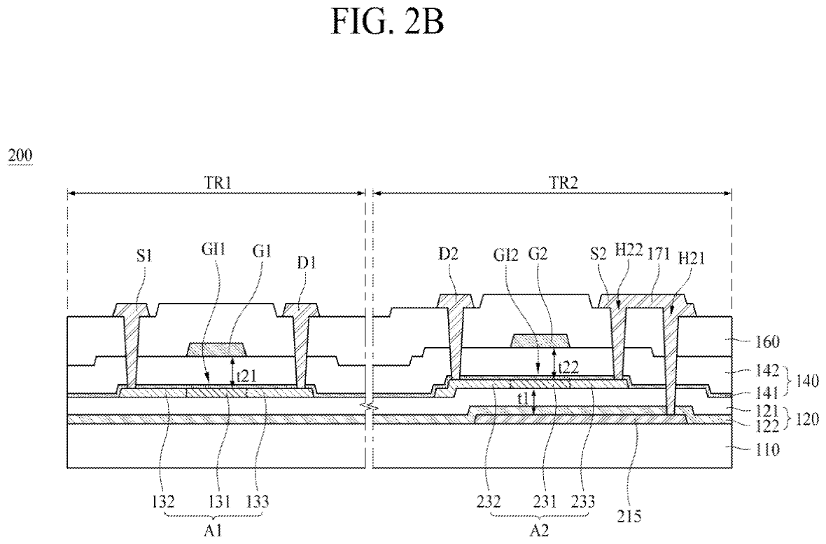

FIGS. 2A and 2B are cross-sectional views illustrating a thin film transistor substrate 200 according to another aspect of the present disclosure. Hereinafter, a description of the elements which are already described, will be omitted to avoid redundancy.

Referring to FIG. 2A, the first buffer layer 120 may have a multi-layered structure. When the first buffer layer 120 is thin, the first channel portion 131 and the second channel portion 231 are conductorized due to the influence of hydrogen (H) present in the insulating layer or the like, so that the first thin film transistor TR1 and the second thin film transistor TR2 may lose their transistor functions.

In order to prevent the first channel portion 131 and the second channel portion 231 from being conductorized, the first buffer layer 120 may include a hydrogen blocking layer 122. The hydrogen blocking layer 122 may be disposed on the conductive material layer 215.

In detail, in the thin film transistor substrate 200 according to another aspect of the present disclosure, the first buffer layer 120 may include a hydrogen blocking layer 122 on the conductive material layer 215 and a buffer insulating layer 121 on the hydrogen blocking layer 122. Hydrogen (H) is blocked by the hydrogen blocking layer 122, whereby the first channel portion 131 and the second channel portion 231 may be effectively prevented from being conductorized.

The hydrogen blocking layer 122 may include silicon nitride (SiNx). Silicon nitride (SiNx) is known as a material having excellent hydrogen (H) blocking capability.

In consideration of film stability and electrical insulation property of the first buffer layer 120, the hydrogen blocking layer 122 may have a thickness of 10 nm to 100 nm. When the thickness of the hydrogen blocking layer 122 is less than 10 nm, the hydrogen blocking capability may be deteriorated, and when the thickness of the hydrogen blocking layer 122 exceeds 100 nm, the thickness of the buffer insulating layer 121 becomes relatively small, whereby film stability and electrical insulation property of the first buffer layer 120 may be deteriorated.

The buffer insulating layer 121 may serve to improve film stability and electrical insulation property of the first buffer layer 120. The buffer insulating layer 121 may include silicon oxide (SiOx). The buffer insulating layer 121 may have a thickness of 40 to 250 nm. When the thickness of the buffer insulating layer 121 is less than 40 nm, film stability and electrical insulation property of the first buffer layer 120 may be deteriorated, and when the thickness of the buffer insulating layer 121 exceeds 250 nm, the thickness of the first buffer layer 120 may be greater than necessary. The buffer insulating layer 121 may have a thickness of 40 to 250 nm.

When the first buffer layer 120 includes both the hydrogen blocking layer 122 and the buffer insulating layer 121, even though the first buffer layer 120 has a thin thickness t1 of about 50 nm, the first channel portion 131 and the second channel portion 231 may be effectively prevented from being conductorized, and the first buffer layer 120 may have excellent film stability and electrical insulation property.

Referring to FIG. 2A, the first gate insulating layer GI1 and the second gate insulating layer GI2 are integrally formed. According to another aspect of the present disclosure, the first gate insulating layer GI1 and the second gate insulating layer GI2 may be collectively referred to as the gate insulating layer 140. According to another aspect of the present disclosure, the gate insulating layer 140 may be disposed over the entire surface of the substrate 110. In this case, the first gate insulating layer GI1 and the second gate insulating layer GI2 do not need to be distinguished from each other. For convenience, the gate insulating layer 140 between the first channel portion 131 and the first gate electrode G1 is referred to as the first gate insulating layer GI1, and the gate insulating layer 140 between the second channel portion 231 and the second gate electrode G2 is referred to as the second gate insulating layer GI2.

Referring to FIG. 2A, since the first gate insulating layer GI1 and the second gate insulating layer GI2 are integrally formed, the thickness t21 of the first gate insulating layer GI1 and the thickness t22 of the second gate insulating layer GI2 are the same each other (t21=t22).

According to another aspect of the present disclosure, at least one of the first gate insulating layer GI1 or the second gate insulating layer GI2 may include an interface layer 141 and a gate insulator 142 on the interface layer 141. The interface layer 141 may be disposed to be closer to one of the first channel portion 131 and the second channel portion 231 than the gate insulator 142. The interface layer 141 may be disposed in contact with the first channel portion 131 and the second channel portion 231.

Referring to FIG. 2B, the gate insulating layer 140 includes an interface layer 141 and a gate insulator 142 on the interface layer 141. The interface layer 141 is disposed to be closer to the first channel portion 131 and the second channel portion 231 than the gate insulator 142. According to another aspect of the present disclosure, as shown in FIG. 2B, the interface layer 141 is in contact with each of the first channel portion 131 and the second channel portion 231.

The interface layer 141 protects the first channel portion 131 and the second channel portion 231. According to another aspect of the present disclosure, the interface layer 141 may be formed by a metal organic chemical vapor deposition (MOCVD) method. The interface layer 141 formed by the MOCVD method has a dense and uniform atomic arrangement structure, thereby effectively blocking hydrogen (H), oxygen (O), etc., which are permeated from the outside of the gate insulating layer 140. As a result, the first channel portion 131 and the second channel portion 231 may be efficiently protected.

The interface layer 141 may be made of an insulating material. For example, the interface layer 141 may include a material that has insulation property and may be applied to the MOCVD method. According to one aspect of the present disclosure, the interface layer 141 may include at least one of silicon oxide (SiOx), silicon nitride (SiNx) or metal oxide. In detail, the interface layer 141 may include at least one of SiO₂, SiNx or Al₂O₃. In more detail, the interface layer 141 may include SiO₂ as silicon oxide (SiOx), but one aspect of the present disclosure is not limited thereto. The interface layer 141 may be formed by other materials having insulation property.

According to another aspect of the present disclosure, the interface layer 141 may have a thickness of 1 nm to 10 nm. When the thickness of the interface layer 141 is less than 1 nm, the effect of blocking hydrogen (H) and oxygen (O) by the interface layer 141 may be reduced. When the thickness of the interface layer 141 exceeds 10 nm, a long time may be required to form the interface layer 141, and the entire thickness of the gate insulating layer 140 may be thicker than necessary.

The gate insulator 142 is a main body of the gate insulating layer 140. Due to the gate insulator 142, the gate insulating layer 140 may have excellent mechanical stability and electrical insulation property, and may have dielectric characteristics required for driving the thin film transistors TR1 and TR2.

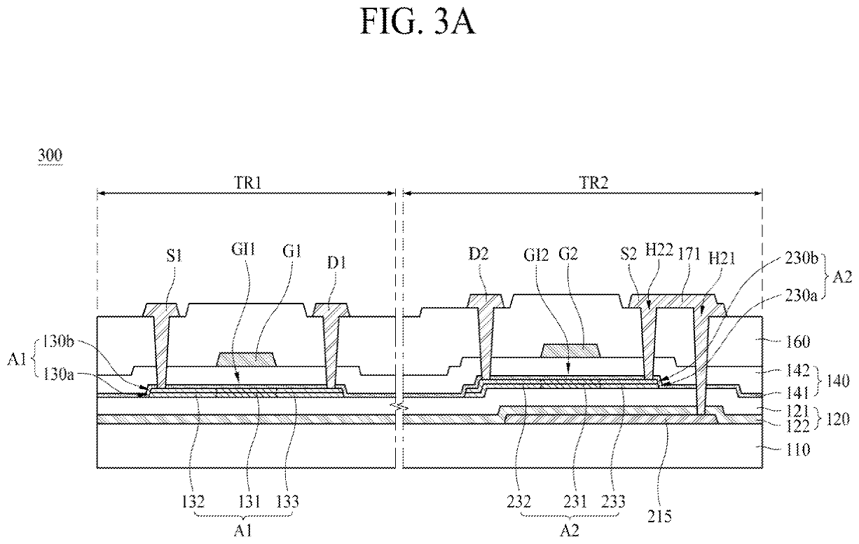

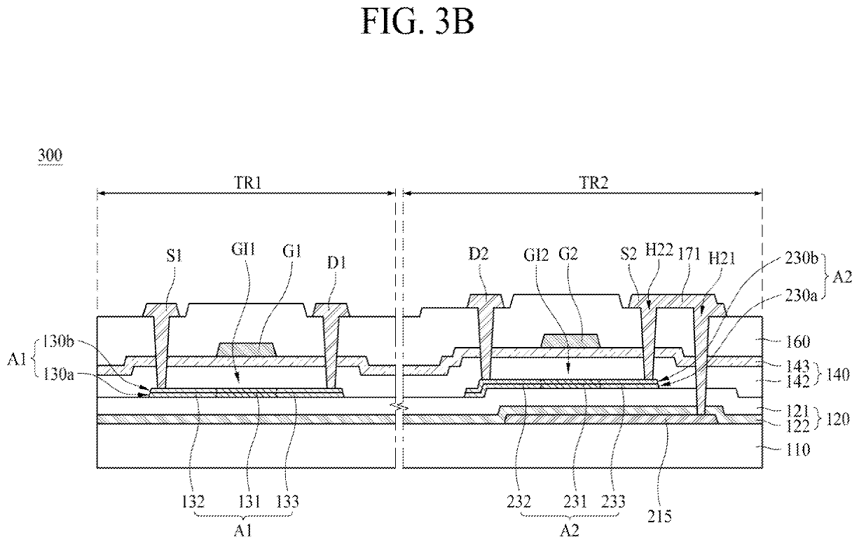

FIGS. 3A and 3B are cross-sectional views illustrating a thin film transistor substrate 300 according to still another aspect of the present disclosure.

The thin film transistor substrate 300 of FIG. 3A includes the first active layer A1 and the second active layer A2 of a multi-layered structure as compared with the thin film transistor substrate 200 of FIG. 2B.

In detail, at least one of the first active layer A1 or the second active layer A2 may include first oxide semiconductor layers 130a and 230a on the substrate 110, and second oxide semiconductor layers 130b and 230b on the first oxide semiconductor layers 130a and 230a. The first oxide semiconductor layers 130a and 230a and the second oxide semiconductor layers 130b and 230b may include the same semiconductor material, or may include different semiconductor materials.

The first oxide semiconductor layers 130a and 230a support the second oxide semiconductor layers 130b and 230b. Therefore, the first oxide semiconductor layers 130a and 230a are referred to as “support layers”. The first channel portion 131 and the second channel portion 231 may be formed in the second oxide semiconductor layers 130b and 230b, respectively. Therefore, the second oxide semiconductor layers 130b and 230b are referred to as “channel layers”, but one aspect of the present disclosure is not limited thereto. The first channel portion 131 and the second channel portion 231 may be formed in the first oxide semiconductor layers 130a and 230a.

The first oxide semiconductor layers 130a and 230a and the second oxide semiconductor layers 130b and 230b may be formed by deposition, metal organic chemical vapor deposition MOCVD or the like. The first oxide semiconductor layers 130a and 230a and the second oxide semiconductor layers 130b and 230b may be formed by a continuous process.

The structure in which the first active layer A1 and the second active layer A2 include the first oxide semiconductor layers 130a and 230a and the second oxide semiconductor layers 130b and 230b is referred to as a bi-layer structure, but another aspect of the present disclosure is not limited thereto. At least one of the first active layer A1 or the second active layer A2 may further include a third oxide semiconductor layer on the second oxide semiconductor layers 130b and 230b.

According to still another aspect of the present disclosure, at least one of the first gate insulating layer GI1 or the second gate insulating layer GI2 may include a gate insulator 142 and a passivation layer 143 on the gate insulator 142. The passivation layer 143 may be disposed to be closer to one of the first gate electrode G1 and the second gate electrode G2 than the gate insulator 142.

Referring to FIG. 3B, the gate insulating layer 140 includes a gate insulator 142 and a passivation layer 143 on the gate insulator 142. The passivation layer 143 may be in contact with the first gate electrode G1 and the second gate electrode G2, respectively.

The passivation layer 143 improves surface characteristics of the gate insulating layer 140. According to still another aspect of the present disclosure, the passivation layer 143 may be formed by the MOCVD method. The passivation layer 143 formed by the MOCVD method has a dense and uniform atomic arrangement structure, thereby effectively blocking hydrogen (H), oxygen (O), etc., which are permeated from the outside of the gate insulating layer 140. As a result, the channel portions 131 and 132 may be efficiently protected.

The passivation layer 143 may be made of an insulating material. For example, the passivation layer 143 may include a material that has insulation property and may be applied to the MOCVD method. According to one aspect of the present disclosure, the passivation layer 143 may include at least one of silicon oxide (SiOx), silicon nitride (SiNx) or metal oxide. In detail, the passivation layer 143 may include at least one of SiO₂, SiNx or Al₂O₃.

According to still another aspect of the present disclosure, the passivation layer 143 may have a thickness of 1 nm to 10 nm. When the thickness of the passivation layer 143 is less than 1 nm, the blocking effect of hydrogen (H) and oxygen (O) by the passivation layer 143 may not be perfect. When the thickness of the passivation layer 143 exceeds 10 nm, a long time may be required to form the passivation layer 143, and the entire thickness of the gate insulating layer 140 may be thicker than necessary.

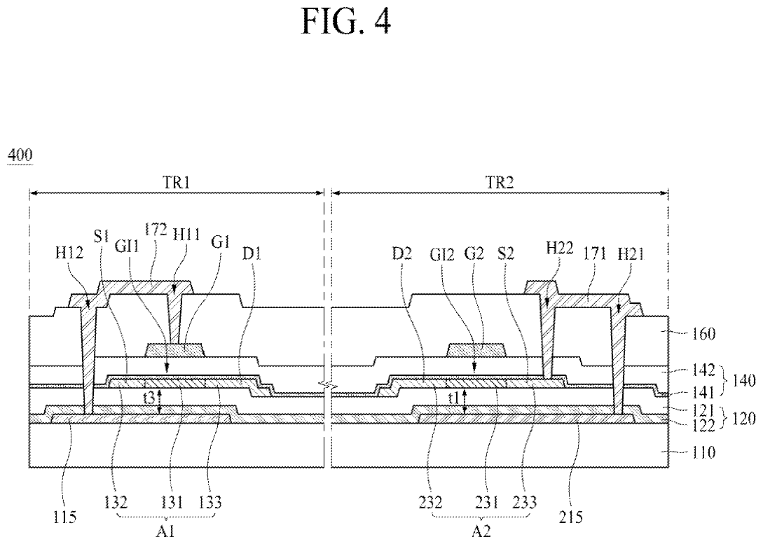

FIG. 4 is a cross-sectional view illustrating a thin film transistor substrate 400 according to further still another aspect of the present disclosure.

The thin film transistor substrate 400 of FIG. 4 further includes a first pad layer 115, which overlaps the first channel portion 131, as compared with the TFT substrate 200 of FIG. 2B.

Referring to FIG. 4, the first pad layer 115 is disposed between the substrate 110 and the first buffer layer 120, and overlaps the first channel portion 131. The first pad layer 115 does not overlap the second channel portion 231.

The first pad layer 115 may have conductivity and light shielding properties. The first pad layer 115 may be a light shielding layer.

According to further still another aspect of the present disclosure, the first buffer layer 120 is disposed on the first pad layer 115. The first pad layer 115 and the first channel portion 131 are spaced apart from each other by the first buffer layer 120. Referring to FIG. 4, a gap distance t3 between the first pad layer 115 and the first channel portion 131 is substantially the same as the thickness t1 of the first buffer layer 120. Therefore, the gap distance t3 between the first pad layer 115 and the first channel portion 131 may be equal to a gap distance t1 between the conductive material layer 215 and the second channel portion 231.

According to further still another aspect of the present disclosure, the first pad layer 115 is connected to the first gate electrode G1. In detail, referring to FIG. 4, a bridge 172 is disposed on the interlayer insulating layer 160, and the first pad layer 115 and the first gate electrode G1 are connected to each other by the bridge 172.

Referring to FIG. 4, the first conductorization portion 132 of the first active layer A1 serves as the first source electrode S1, and the second conductorization portion 133 serves as the first drain electrode D1. In addition, the first conductorization portion 232 of the second active layer A2 serves as the second drain electrode D2, and the second conductorization portion 233 serves as the second source electrode S2.

The bridge 172 connects the first gate electrode G1 with the first pad layer 115 through the contact holes H11 and H12. One H11 of the contact holes H11 and H12 is formed by passing through the interlayer insulating layer 160, and the other one H21 is formed by passing through the interlayer insulating layer 160, the gate insulating layer 140 and the first buffer layer 120.

Referring to FIG. 4, since the first pad layer 115 is connected to the first gate electrode G1, the first thin film transistor TR1 of FIG. 4 may have a double gate structure. Due to the double gate structure, the first thin film transistor TR1 of FIG. 4 may have a very small s-factor.

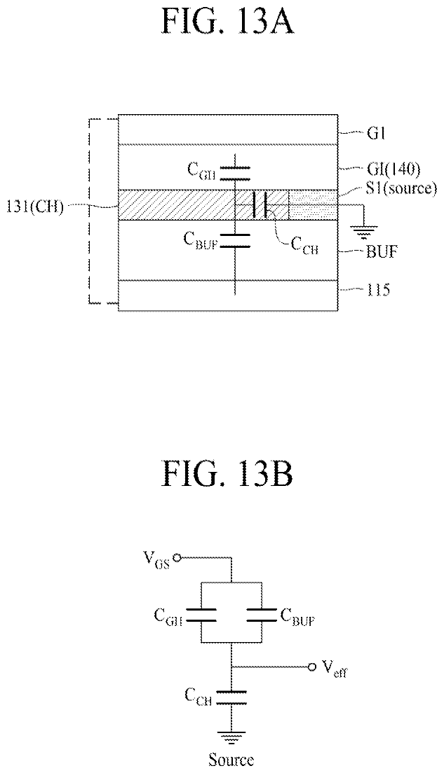

The effective gate voltage V_{eff} by the first pad layer 115 may be described by FIGS. 13A and 13B.

FIGS. 13A and 13B are schematic views illustrating an effective gate voltage V_{eff} of a first thin film transistor according to another aspect of the present disclosure.

FIG. 13A schematically illustrates capacitance Cap that may occur when a gate voltage V_{GS} is applied to the first thin film transistor TR1 of FIG. 4. In FIG. 13A, before the first thin film transistor TR1 is completely turned on, the relation of the capacitance Cap in a voltage near the threshold voltage Vth is schematically illustrated.

As shown in FIG. 13A, when the gate voltage V_{GS} is applied to the second thin film transistor TR2, capacitance C_{GI1} may be formed between the first channel portion 131 and the first gate electrode G1, capacitance C_{CH} may be formed between the first channel portion 131 and the first source electrode S1, and capacitance C_{BUF} may be formed between the first channel portion 131 and the first pad layer 115.

The relation between the voltage and the capacitance Cap according to FIG. 13A may be expressed as shown in FIG. 13B.

According to one aspect of the present disclosure, the first pad layer 115 and the first gate electrode G1 are electrically connected to each other. Therefore, an effect of applying a gate voltage to the first channel portion by the first pad layer 115 is generated. As a result, the effective gate voltage V_{eff} corresponding to the capacitance C_{BUF} between the first channel portion 131 and the first pad layer 115 is increased.

Referring to FIG. 13B, when a voltage applied between the first channel portion 131 and the first gate electrode G1 is referred to as an effective gate voltage V_{eff} during driving of the first thin film transistor TR1, the effective gate voltage V_{eff} may be obtained by the following Equation 4.

V_{eff}=[C_{GI1}+C_{BUF})/(C_{GI1}+C_{CH}+C_{BUF})]×V_{GS} [Equation 4]

Referring to the Equation 4, due to the capacitance C_{BUF} between the first channel portion 131 and the first pad layer 115, a molecular portion of the Equation 4 was increased as compared with the Equation 2. Therefore, the effective gate voltage V_{eff} is little reduced as compared with the gate voltage V_{GS} actually applied between the first source electrode S1 and the first gate electrode G1. Therefore, when the same voltage is applied, the drain-source current I_{DS} of the first thin film transistor TR1 is larger than the drain-source current I_{DS} of the second thin film transistor TR2, and the change level of the drain-source current I_{DS} is also large.

As described above, since the change in the drain-source current I_{DS} of the first thin film transistor TR1 is larger than that of the second thin film transistor TR2, the first thin film transistor TR1 has a smaller s-factor than the second thin film transistor TR2.

Therefore, in the thin film transistor substrate 400 shown in FIG. 4, the first thin film transistor TR1 having a very small s-factor may be used as a switching transistor, and the second thin film transistor TR2 having a relatively large s-factor may be used as a driving transistor of the display device.

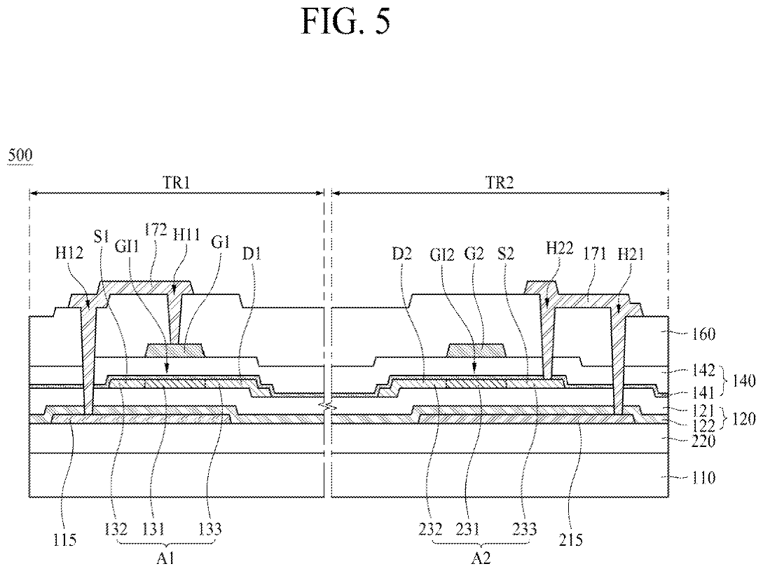

FIG. 5 is a cross-sectional view illustrating a thin film transistor substrate 500 according to further still another aspect of the present disclosure.

Referring to FIG. 5, the thin film transistor substrate 500 according to further still another aspect of the present disclosure further includes a second buffer layer 220 between the substrate 110 and the first buffer layer 120. The second buffer layer 220 has insulation property, and may prevent permeation of moisture and oxygen.

The second buffer layer 220 may include at least one of silicon oxide, silicon nitride or metal-based oxide. The second buffer layer 220 may have a single layered structure, or may have a multi-layered structure.

According to one aspect of the present disclosure, the second buffer layer 220 may have the same thickness as that of the first buffer layer 120, or may have a thickness greater than that of the first buffer layer 120. For example, the second buffer layer 220 may have a thickness of 1.5 times or more as compared with the first buffer layer 120. The second buffer layer 220 may have a thickness of at least twice or three times as compared with the first buffer layer 120.

Referring to FIG. 5, the conductive material layer 215 may be disposed between the first buffer layer 120 and the second buffer layer 220. The first pad layer 115 may also be disposed between the first buffer layer 120 and the second buffer layer 220.

In the thin film transistor substrate 500 according to further still another aspect of the present disclosure shown in FIG. 5, the first pad layer 115 is electrically connected to the first gate electrode G1 in the same manner as FIG. 4. The first pad layer 115 is connected to the first gate electrode G1 through the bridge 172 and the contact holes H11 and H12.

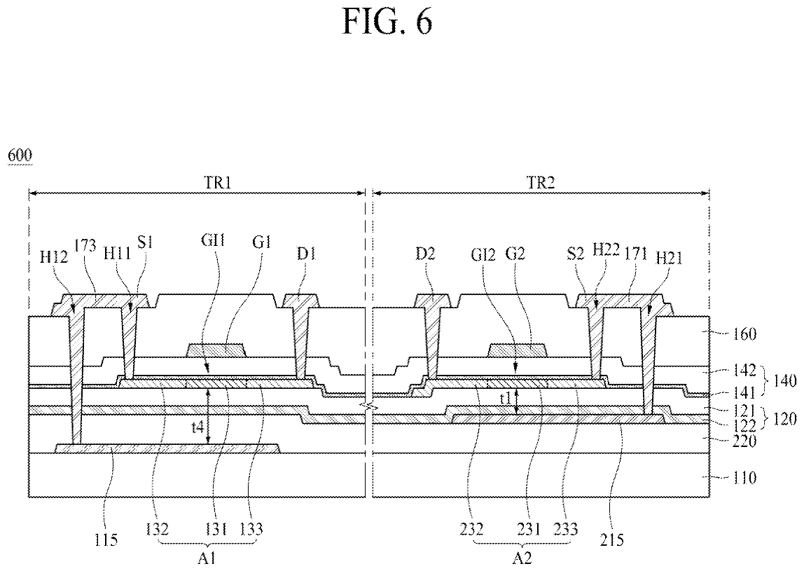

FIG. 6 is a cross-sectional view illustrating a thin film transistor substrate 600 according to further still another aspect of the present disclosure.

Referring to FIG. 6, the first pad layer 115 may be disposed between the substrate 110 and the second buffer layer 220. The first pad layer 115 is connected to the first source electrode S1 of the first thin film transistor TR1.

Referring to FIG. 6, a bridge 173 is disposed on the interlayer insulating layer 160, and thus the first pad layer 115 and the first source electrode S1 are connected to each other by the bridge 173. The bridge 173 may be extended from the first source electrode S1, and a portion of the first source electrode S1 may serve as the bridge 173.

The bridge 173 is connected to the first pad layer 115 through the contact hole H12. The contact hole H21 is formed by passing through the interlayer insulating layer 160, the gate insulating layer 140, the first buffer layer 120 and the second buffer layer 220.

When the first conductorization portion 132 of the first active layer A1 serves as the first source electrode S1 and the second conductorization portion 133 serves as the first drain electrode D1, the first source electrode S1 and the first drain electrode D1 on the interlayer insulating layer 160 may be omitted. In this case, the first source electrode S1 on the interlayer insulating layer 160 may be a portion of the bridge 173.

Referring to FIG. 6, the bridge 173 may connect the first conductorization portion 132 of the first active layer A1 with the first pad layer 115 through the two contact holes H11 and H12.

In the thin film transistor substrate 600 of FIG. 6, since the first pad layer 115 is connected to the first source electrode S1, capacitance Cap may be formed between the first pad layer 115 and the first channel portion 131. However, since the distance between the first pad layer 115 and the first channel portion 131 is long, the capacitance between the first pad layer 115 and the first channel portion 131 is very small. Therefore, the capacitance Cap between the first pad layer 115 and the first channel portion 131 little affects the gate voltage V_{GS} and the effective gate voltage V_{eff}.

According to one aspect of the present disclosure, a distance t4 between the first pad layer 115 and the first channel portion 131 is longer than the distance t1 between the conductive material layer 215 and the second channel portion 231. For example, the distance t4 between the first pad layer 115 and the first channel portion 131 may be at least twice the distance t1 between the conductive material layer 215 and the second channel portion 231 (t4≥2×t1). In more detail, the distance t4 between the first pad layer 115 and the first channel portion 131 may be at least 2.5 times the distance t1 between the conductive material layer 215 and the second channel portion 231.

As described above, even though the first pad layer 115 is disposed below the first channel portion 131 of the first thin film transistor TR1 and the first pad layer 115 is connected to the first source electrode S1, since the distance between the first pad layer 115 and the first channel portion 131 is long, the s-factor of the first thin film transistor TR1 is little increased. As a result, the first thin film transistor TR1 may maintain excellent switching characteristics.

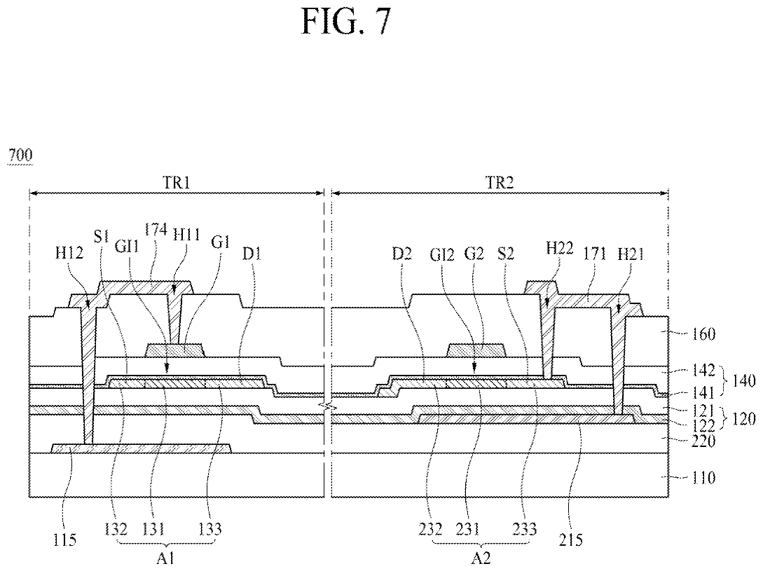

FIG. 7 is a cross-sectional view illustrating a thin film transistor substrate 700 according to further still another aspect of the present disclosure.

Referring to FIG. 7, the first pad layer 115 is connected to the first gate electrode G1. In detail, a bridge 174 is disposed on the interlayer insulating layer 160, and the first pad layer 115 and the first gate electrode G1 are connected to each other by the bridge 174.

Referring to FIG. 7, the first conductorization portion 132 of the first active layer A1 serves as the first source electrode S1, and the second conductorization portion 133 serves as the first drain electrode D1. In addition, the first conductorization portion 232 of the second active layer A2 serves as the second drain electrode D2, and the second conductorization portion 233 serves as the second source electrode S2.

The bridge 174 connects the first gate electrode G1 with the first pad layer 115 through the contact holes H11 and H12. One H11 of the contact holes H11 and H12 is formed by passing through the interlayer insulating layer 160, and the other one H21 is formed by passing through the interlayer insulating layer 160, the gate insulating layer 140, the first buffer layer 120 and the second buffer layer 220.

Referring to FIG. 7, since the first pad layer 115 is connected to the first gate electrode G1, the first thin film transistor TR1 of FIG. 7 may have a double gate structure.

However, since the distance between the first pad layer 115 and the first channel portion 131 is long, the capacitance Cap between the first pad layer 115 and the first channel portion 131 is very small. Therefore, the capacitance Cap between the first pad layer 115 and the first channel portion 131 may little affect the gate voltage V_{GS} and the effective gate voltage V_{eff}.

FIGS. 8A to 8E are graphs illustrating threshold voltages for thin film transistors. The threshold voltage graph for the thin film transistors is represented by a graph of the drain-source current I_{DS} for the gate voltage V_{GS} of the thin film transistor, as disclosed in FIGS. 8A to 8E.

In detail, the thin film transistors of FIGS. 8A to 8E, which are for measurement, have the same structure as that of the thin film transistor TR2 shown in FIG. 1A.

The thin film transistors of FIGS. 8A, 8B, 8C and 8D, which are for measurement, include a gate insulating layer having a thickness of 250 nm and first buffer layers 120 having thicknesses of 82 nm, 120 nm, 182 nm and 232 nm, respectively. The thin film transistor of FIG. 8E includes a gate insulating layer having a thickness of 150 nm and a first buffer layer 120 having a thickness of 400 nm.

The thin film transistors according to FIGS. 8A, 8B, 8C and 8D, which include the first buffer layer 120 thinner than the gate insulating layer, were confirmed to have s-factors of 0.38, 0.36, 0.31 and 0.31(V/decade), respectively.

The thin film transistor according to FIG. 8E, which includes the first buffer layer 120 thicker than the gate insulating layer, was confirmed to have an s-factor of 0.19(V/decade).

Referring to FIGS. 8A to 8E, when the thickness t1 of the first buffer layer 120 and the thickness t22 of the gate insulating layer [second gate insulating layer GI2] satisfy the relation of Equation 3, it may be confirmed that the thin film transistor has an s-factor of 0.3(V/decade) or more.

0.75≤t22/t1≤5 [Equation 3]

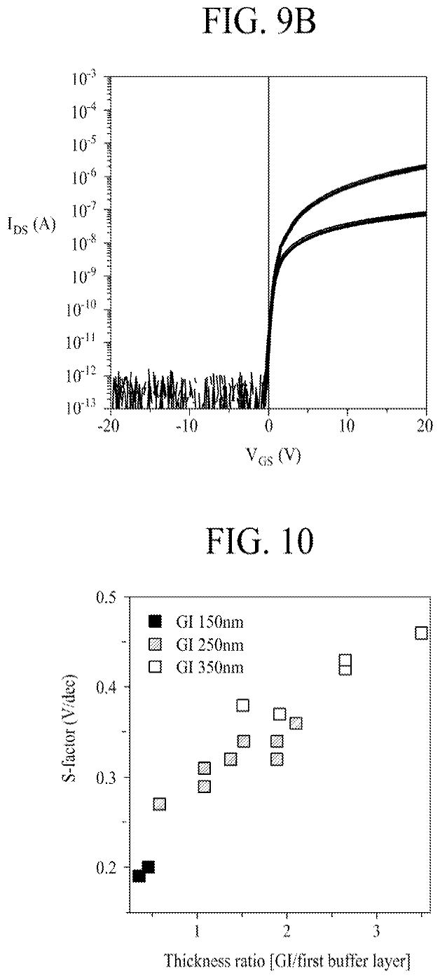

FIGS. 9A and 9B are graphs illustrating threshold voltages for thin film transistors. The threshold voltage graph for the thin film transistors is represented by a graph of the drain-source current I_{DS} for the gate voltage V_{GS}.

The thin film transistors of FIGS. 9A and 9B, which are for measurement, have the same structure as that of the thin film transistor TR2 shown in FIG. 2A. The thin film transistors of FIGS. 9A and 9B, which are for measurement, include a gate insulating layer 140 having a thickness of 350 nm and first buffer layers 120 having thicknesses of 110 nm and 130 nm, respectively.

In detail, the first buffer layer 120 of the thin film transistor of FIG. 9A, which is for measurement, includes a hydrogen blocking layer 122 having a thickness of 10 nm and a buffer insulating layer 121 having a thickness of 100 nm. The first buffer layer 120 of the thin film transistor of FIG. 9B, which is for measurement, includes a hydrogen blocking layer 122 having a thickness of 30 nm and a buffer insulating layer 121 having a thickness of 100 nm. The hydrogen blocking layer 122 is made of silicon nitride (SiNx), and the buffer insulating layer 121 is made of silicon oxide (SiOx).

It was confirmed that the thin film transistor shown in FIG. 9A has an s-factor of 0.51 (V/decade), and the thin film transistor according to FIG. 9B has an s-factor of 0.49 (V/decade). In this way, according to one aspect of the present disclosure, the thin film transistor may have an s-factor of 0.45 (V/decade) or more.

FIG. 10 is a graph for a relation between an s-factor and a thickness ratio of a first buffer layer and a gate insulating layer.

In detail, FIG. 10 shows an s-factor according to a thickness ratio [GI/first buffer layer] of the first buffer layer 120 and the gate insulating layer GI when the thicknesses of the gate insulating layer GI (second gate insulating layer of FIG. 2A) are 150 nm, 250 nm and 350 nm, respectively, in the thin film transistor having the same structure as that of the thin film transistor TR2 shown in FIG. 2A.

Referring to FIG. 10, when the thickness of the gate insulating layer GI is 250 nm or more, and when the thickness ratio [GI/the first buffer layer] of the gate insulating layer GI to the first buffer layer 120 is 0.75 or more, the thin film transistor may have an s-factor of 0.3 or more.

Further still another aspect of the present disclosure provides a display device 800 that includes thin film transistor substrates 100, 200, 300, 400, 500, 600 and 700 and a display element 710 connected to the second thin film transistor TR2 of the thin film transistor substrates 100, 200, 300, 400, 500, 600 and 700. According to further still another aspect of the present disclosure, the display element 710 may include, for example, an organic light emitting diode.

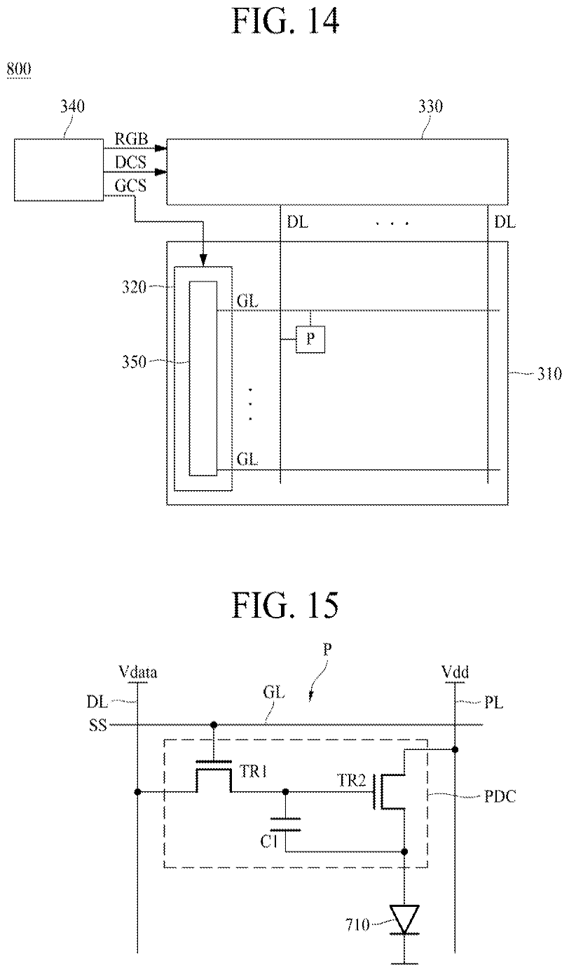

FIG. 14 is a schematic view illustrating a display device 800 according to further still another aspect of the present disclosure.

As shown in FIG. 14, the display device 800 according to further still another aspect of the present disclosure includes a display panel 310, a gate driver 320, a data driver 330 and a controller 340.

Gate lines GL and data lines DL are disposed in the display panel 310, and a pixel P is disposed in an intersection area of the gate lines GL and the data lines DL. An image is displayed by driving of the pixel P.

The controller 340 controls the gate driver 320 and the data driver 330.

The controller 340 outputs a gate control signal GCS for controlling the gate driver 320 and a data control signal DCS for controlling the data driver 330 by using a signal supplied from an external system (not shown). Further, the controller 340 samples input image data input from the external system, realigns the sampled input image data and supplies the realigned digital image data RGB to the data driver 330.

The gate control signal GCS includes a gate start pulse GSP, a gate shift clock GSC, a gate output enable signal GOE, a start signal Vst and a gate clock GCLK. Further, control signals for controlling a shift register may be included in the gate control signal GCS.

The data control signal DCS includes a source start pulse SSP, a source shift clock signal SSC, a source output enable signal SOE, a polarity control signal POL, etc.

The data driver 330 supplies a data voltage to the data lines DL of the display panel 310. In detail, the data driver 330 converts the image data RGB input from the controller 340 into an analog data voltage and supplies the data voltage to the data lines DL.

The gate driver 320 may include a shift register 350.

The shift register 350 sequentially supplies gate pulses to the gate lines GL during one frame by using the start signal and the gate clock, which are transmitted from the controller 340. In this case, one frame refers to a period at which one image is output through the display panel 310. The gate pulse has a turn-on voltage capable of turning on a switching element (thin film transistor) disposed in the pixel P.

In addition, the shift register 350 supplies a gate-off signal capable of turning off the switching element to the gate line GL during the remaining period of one frame, at which the gate pulse is not supplied. Hereinafter, the gate pulse and the gate-off signal will be collectively referred to as a scan signal SS or Scan.

According to one aspect of the present disclosure, the gate driver 320 may be packaged on the substrate 110. In this way, the structure in which the gate driver 320 is directly packaged on the substrate 110 will be referred to as a gate-in-panel (GIP) structure.

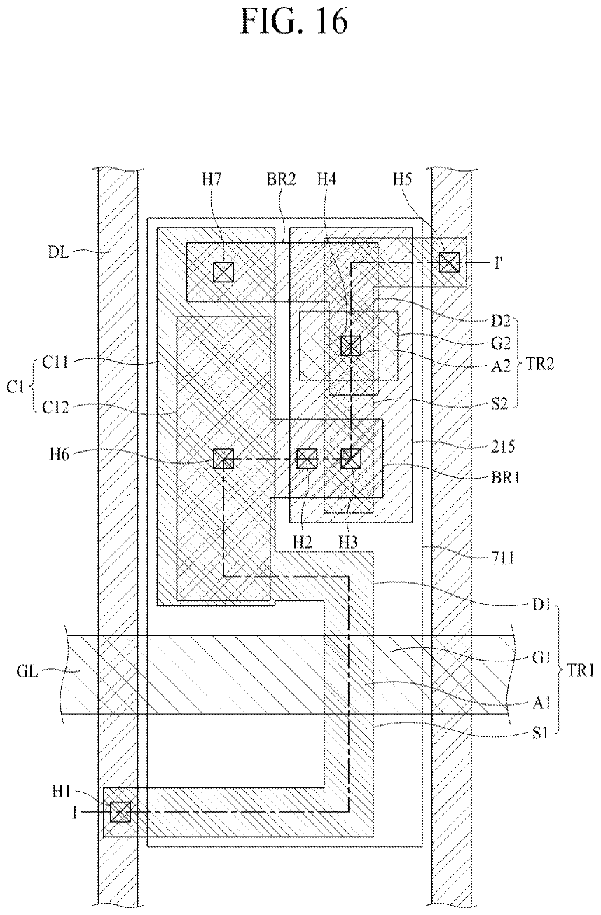

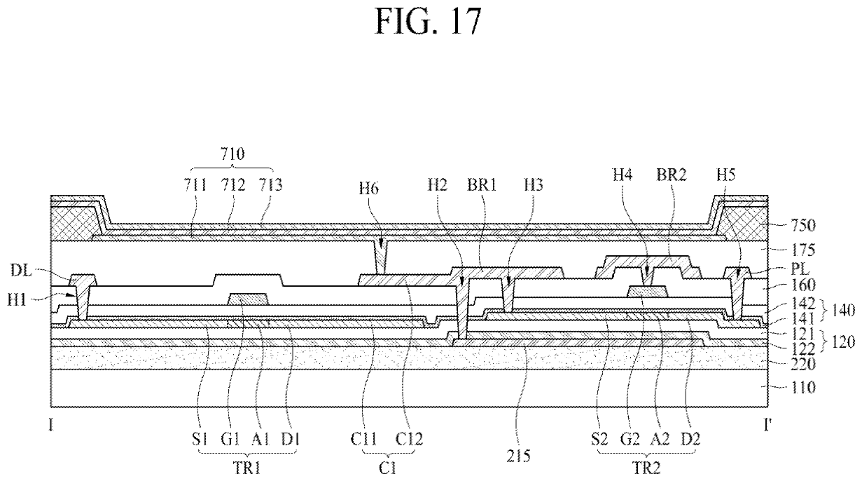

FIG. 15 is a circuit view for any one pixel P of FIG. 14, FIG. 16 is a plan view illustrating the pixel P of FIG. 15, and FIG. 17 is a cross-sectional view taken along line I-I′ of FIG. 16.

The circuit view of FIG. 15 is an equivalent circuit view for the pixel P of the display device 800 that includes an organic light emitting diode (OLED) as the display element 710.

The pixel P includes a display element 710 and a pixel driving circuit PDC for driving the display element 710.

The pixel driving circuit PDC of FIG. 15 includes a first thin film transistor TR1 that is a switching transistor, and a second thin film transistor TR2 that is a driving transistor. The first thin film transistor TR1 and the second thin film transistor TR2 have been already described in the description of the thin film transistor substrates 100, 200, 300, 400, 500, 600 and 700.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls application of the data voltage Vdata.

A driving power line PL provides a driving voltage Vdd to the display element 710, and the second thin film transistor TR2 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to the gate electrode G2 of the second thin film transistor TR2 connected to the display element 710. The data voltage Vdata is charged in a first capacitor C1 formed between the gate electrode G2 and the source electrode S2 of the second thin film transistor TR2. The first capacitor C1 is a storage capacitor Cst.

The amount of a current supplied to the organic light emitting diode (OLED), which is the display element 710, is controlled through the second thin film transistor TR2 in accordance with the data voltage Vdata, whereby a gray scale of light output from the display element 710 may be controlled.

Referring to FIGS. 16 and 17, the first thin film transistor TR1 and the second thin film transistor TR2 are disposed on the substrate 110.

The substrate 110 may be made of glass or plastic. Plastic having flexible property, for example, polyimide (PI), may be used as the substrate 110.

The second buffer layer 220 is disposed on the substrate 110, and the conductive material layer 215 is disposed on the second buffer layer 220. The conductive material layer 215 may have electrical conductivity and light shielding characteristics. The conductive material layer 215 may protect the active layers A1 and A2 by shielding light incident from the outside.

The first buffer layer 120 is disposed on the conductive material layer 215. The first buffer layer 120 is made of an insulating material, and protects the active layers A1 and A2 from moisture or oxygen introduced from the outside. The first buffer layer 120 may include a hydrogen blocking layer 122 and a buffer insulating layer 121.

The first active layer A1 of the first thin film transistor TR1 and the second active layer A2 of the second thin film transistor TR2 are disposed on the first buffer layer 120.

The first active layer A1 and the second active layer A2 may include, for example, an oxide semiconductor material. The first active layer A1 and the second active layer A2 may be formed of an oxide semiconductor layer made of an oxide semiconductor material.

The first active layer A1 may include a first channel portion 131, a first conductorization portion 132 and a second conductorization portion 133. The first channel portion 131 overlaps the first gate electrode G1. According to another aspect of the present disclosure, the first conductorization portion 132 may be referred to as the first source electrode S1, and the second conductorization portion 133 may be referred to as the first drain electrode D1.

The second active layer A2 may include a second channel portion 231, a first conductorization portion 232 and a second conductorization portion 233. The second channel portion 231 overlaps the second gate electrode G2. According to another aspect of the present disclosure, the first conductorization portion 232 may be referred to as the second source electrode S2, and the second conductorization portion 233 may be referred to as the second drain electrode D2.

Referring to FIGS. 16 and 17, a portion of the first active layer A1 may be conductorized and thus may be a first capacitor electrode C11 of the first capacitor C1.

The gate insulating layer 140 is disposed on the first active layer A1 and the second active layer A2. The gate insulating layer 140 may cover an entire upper surface of the first active layer A1 and the second active layer A2, or may cover only a portion of the first active layer A1 and the second active layer A2. The gate insulating layer 140 protects the first channel portion 131 and the second channel portion 231.

The gate insulating layer 140 may include an interface layer 141 and a gate insulator 142 on the interface layer 141. The interface layer 141 is disposed to be closer to the first channel portion 131 and the second channel portion 231 than the gate insulator 142.

The first gate electrode G1 of the first thin film transistor TR1 and the second gate electrode G2 of the second thin film transistor TR2 are disposed on the gate insulating layer 140.

The first gate electrode G1 of the first thin film transistor TR1 overlaps at least a portion of the first active layer A1 of the first thin film transistor TR1. The second gate electrode G2 of the second thin film transistor TR2 overlaps at least a portion of the second active layer A2 of the second thin film transistor TR2.

The interlayer insulating layer 160 is disposed on the first gate electrode G1 and the second gate electrode G2.

The data line DL and the driving power line PL are disposed on the interlayer insulating layer 160.

The data line DL is in contact with the first source electrode S1 formed in the first active layer A1 through a first contact hole H1. According to another aspect of the present disclosure, a portion of the data line DL overlapped with the first active layer A1 may be referred to as the first source electrode S1.

The driving power line PL is in contact with the second drain electrode D2 formed in the second active layer A2 through a fifth contact hole H5. According to another aspect of the present disclosure, a portion of the driving power line PL overlapped with the second active layer A2 may be referred to as the second drain electrode D2.

Referring to FIGS. 16 and 17, a second capacitor electrode C12 of the first capacitor C1, a first bridge BR1 and a second bridge BR2 are disposed on the interlayer insulating layer 160.

The second capacitor electrode C12 overlaps the first capacitor electrode C11 to form the first capacitor C1.

The first bridge BR1 may be integrally formed with the second capacitor electrode C12. The first bridge BR1 is connected to the conductive material layer 215 through a second contact hole H2, and is connected to the second source electrode S2 through a third contact hole H3. As a result, the conductive material layer 215 may be connected to the second source electrode S2 of the second thin film transistor TR2.

The second bridge BR2 is connected to the second gate electrode G2 of the second thin film transistor TR2 through a fourth contact hole H4, and is connected to the first capacitor electrode C11 of the first capacitor C1 through a seventh contact hole H7.

A planarization layer 175 is disposed on the data line DL, the driving power line PL, the second capacitor electrode C12, the first bridge BR1 and the second bridge BR2. The planarization layer 175 planarizes an upper portion of the first thin film transistor TR1 and the second thin film transistor TR2, and protects the first thin film transistor TR1 and the second thin film transistor TR2.

A first electrode 711 of the display element 710 is disposed on the planarization layer 175. The first electrode 711 of the display element 710 is in contact with the second capacitor electrode C12, which is integrally formed with the first bridge BR1, through a sixth contact hole H6 formed in the planarization layer 175. As a result, the first electrode 711 may be connected to the second source electrode S2 of the second thin film transistor TR2.

A bank layer 750 is disposed at an edge of the first electrode 711. The bank layer 750 defines a light emission area of the display element 710.

An organic light emitting layer 712 is disposed on the first electrode 711, and a second electrode 713 is disposed on the organic light emitting layer 712. Therefore, the display element 710 is completed. The display element 710 shown in FIG. 17 is an organic light emitting diode (OLED). Therefore, the display device 100 according to one aspect of the present disclosure is an organic light emitting display device.

According to another aspect of the present disclosure, the second thin film transistor TR2 may have a relatively large s-factor. The second thin film transistor TR2 may be used as a driving transistor to improve a capability of expressing a gray scale of the display device 800.

The first thin film transistor TR1 has a relatively low s-factor, thereby having excellent switching characteristics. The first thin film transistor TR1 may be used as a switching transistor to improve display quality of the display device 800.

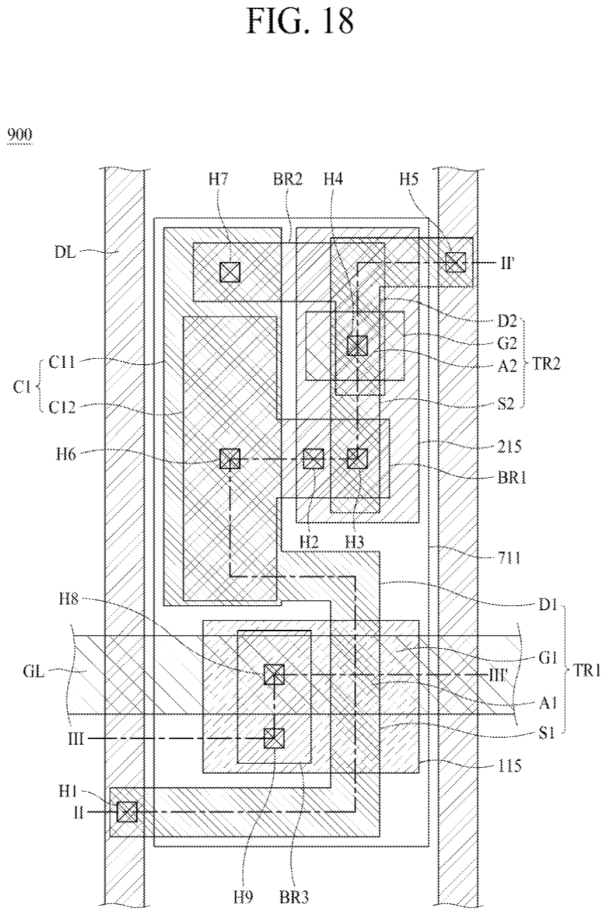

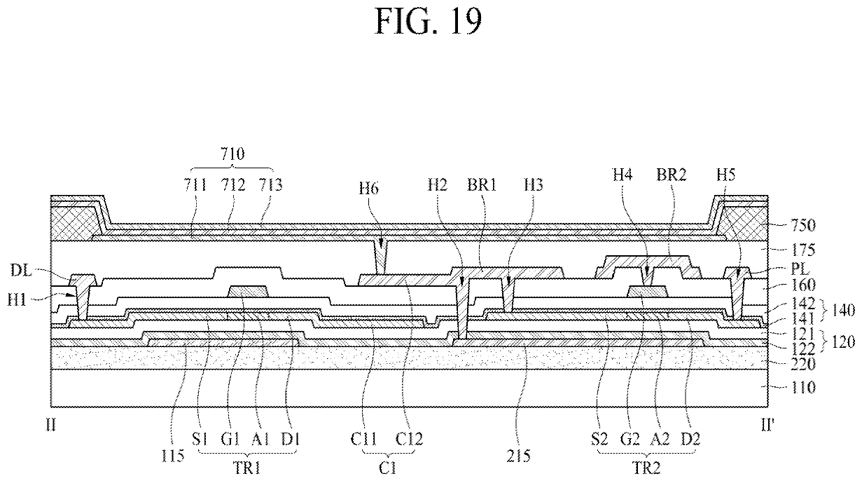

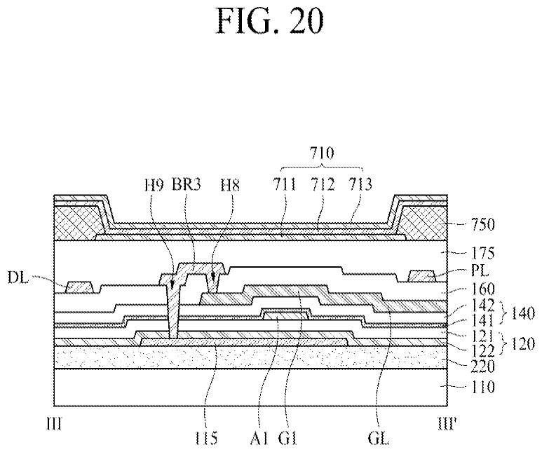

FIG. 18 is a plan view illustrating any one pixel P of a display device 900 according to another aspect of the present disclosure, FIG. 19 is a cross-sectional view taken along line II-II′ of FIG. 18, and FIG. 20 is a cross-sectional view taken along line III-III′ of FIG. 18.

The display device 900 of FIG. 18 further includes a first pad layer 115 overlapped with the first active layer A1 in comparison with the display device 800 shown in FIGS. 14 to 17.

Referring to FIGS. 19 and 20, the first pad layer 115 is disposed between the substrate 110 and the first buffer layer 120. In more detail, the first pad layer 115 is disposed between the first buffer layer 120 and the second buffer layer 220.

The first pad layer 115 overlaps the first channel portion 131 of the first active layer A1 and does not overlap the second channel portion 231 of the second active layer A2.

The first pad layer 115 may have conductivity and light shielding properties. The first pad layer 115 may be a light shielding layer.

Referring to FIGS. 18 and 20, a third bridge BR3 is disposed on the interlayer insulating layer 160. The third bridge BR3 is connected to the gate line GL through an eighth contact hole H8, and is connected to the first pad layer 115 through a ninth contact hole H9. Since the first gate electrode G1 is a portion of the gate line GL, the first pad layer 115 may be connected to the first gate electrode G1 of the first thin film transistor TR1 by the third bridge BR3.

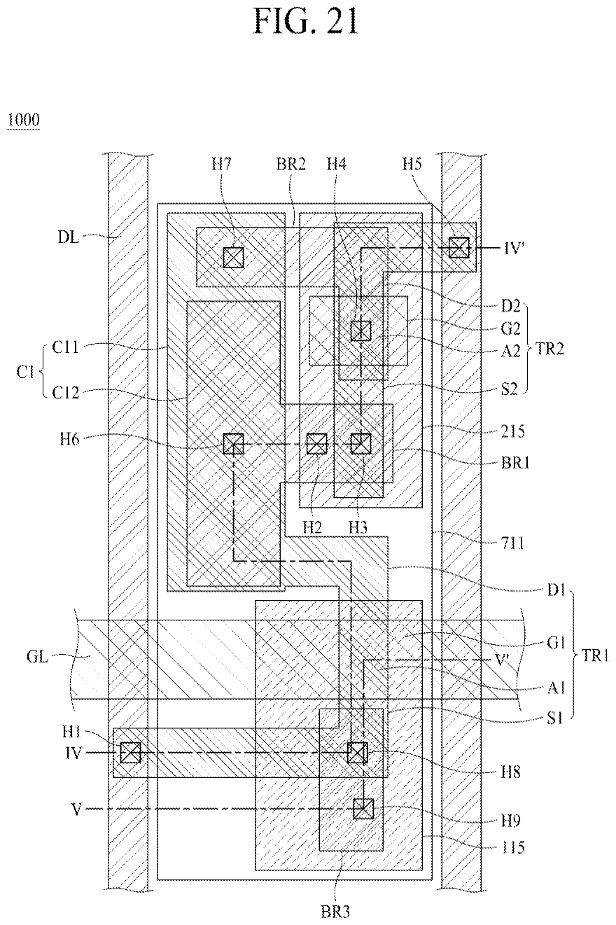

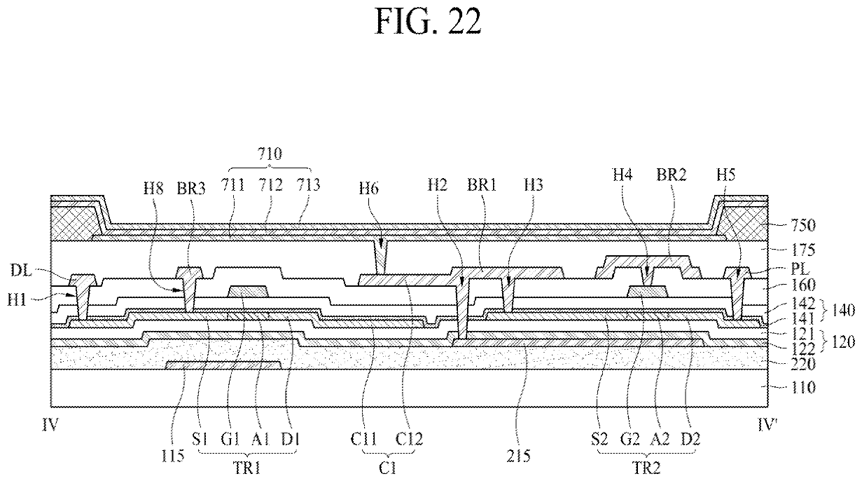

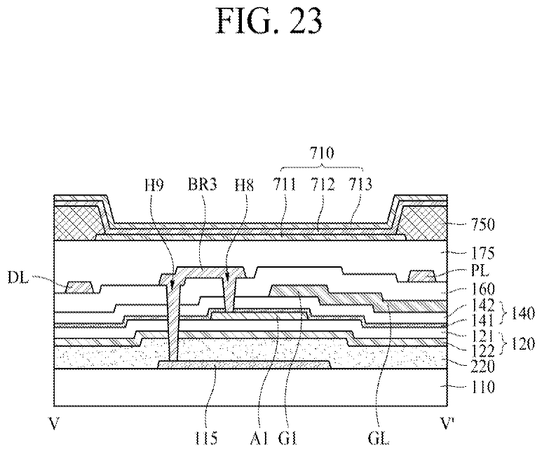

FIG. 21 is a plan view illustrating any one pixel P of a display device 1000 according to still another aspect of the present disclosure, FIG. 22 is a cross-sectional view taken along line IV-IV′ of FIG. 21, and FIG. 23 is a cross-sectional view taken along line V-V′ of FIG. 21.

The display device 1000 of FIG. 21 further includes a first pad layer 115 overlapped with the first active layer A1 in comparison with the display device 800 shown in FIGS. 14 to 17.

Referring to FIGS. 21 to 23, the first pad layer 115 is disposed between the substrate 110 and the first buffer layer 120. In more detail, the first pad layer 115 is disposed between the substrate 110 and the second buffer layer 220.

Referring to FIGS. 21 to 23, the third bridge BR3 is disposed on the interlayer insulating layer 160. The third bridge BR3 is connected to the first source electrode S1 of the first thin film transistor TR1 through the eighth contact hole H8, and is connected to the first pad layer 115 through the ninth contact hole H9. As a result, the first pad layer 115 may be connected to the first source electrode S1 of the first thin film transistor TR1 by the third bridge BR3.

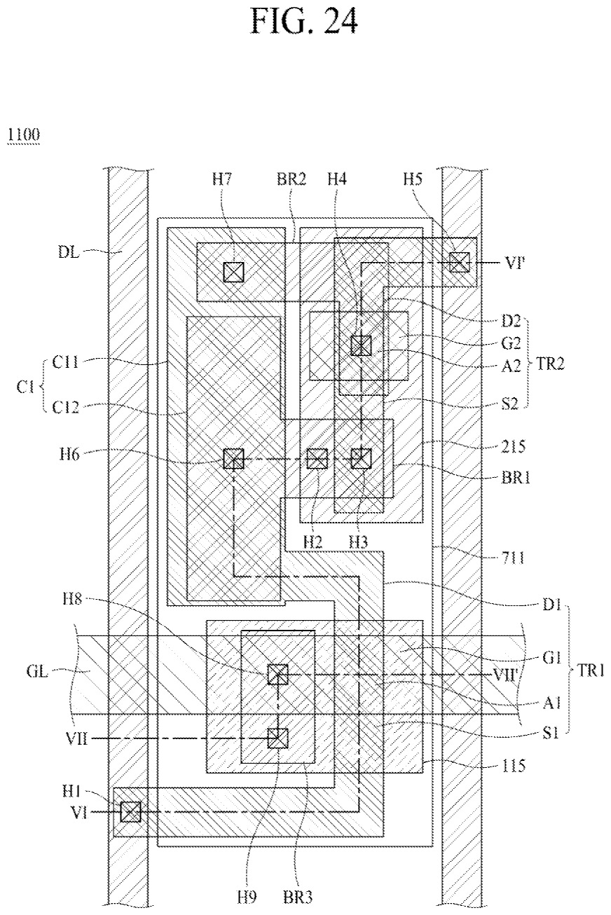

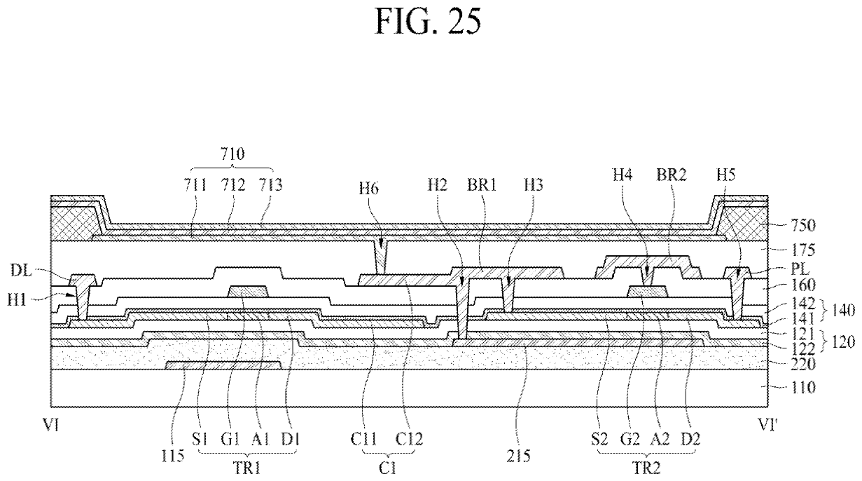

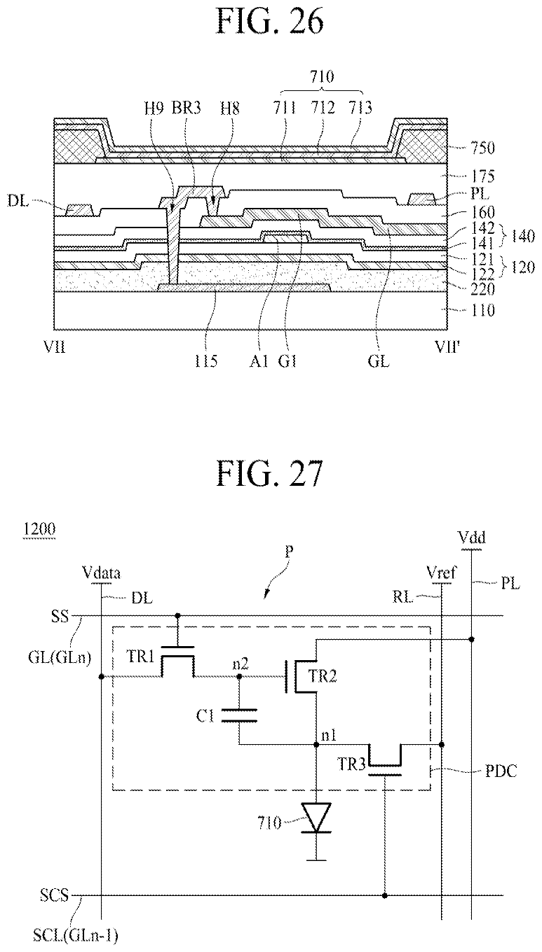

FIG. 24 is a plan view illustrating any one pixel P of a display device 1100 according to further still another aspect of the present disclosure, FIG. 25 is a cross-sectional view taken along line VI-VI′ of FIG. 24, and FIG. 26 is a cross-sectional view taken along line VII-VII′ of FIG. 24.

In the display device 1100 of FIGS. 24 to 26, the first pad layer 115 is disposed between the substrate 110 and the second buffer layer 220 in comparison with the display device 900 of FIGS. 18 to 20.

Referring to FIGS. 24 to 26, the third bridge BR3 is disposed on the interlayer insulating layer 160. The third bridge BR3 is connected to the gate line GL through the eighth contact hole H8, and is connected to the first pad layer 115 through the ninth contact hole H9. Since the first gate electrode G1 is a portion of the gate line GL, the first pad layer 115 may be connected to the first gate electrode G1 of the first thin film transistor TR1 by the third bridge BR3.

FIG. 27 is a circuit view illustrating any one pixel P of a display device 1200 according to further still another aspect of the present disclosure.

FIG. 27 is an equivalent circuit view illustrating a pixel P of an organic light emitting display device.

The pixel P of the display device 1200 shown in FIG. 27 includes an organic light emitting diode (OLED) that is a display element 710 and a pixel driving circuit PDC for driving the display element 710. The display element 710 is connected with the pixel driving circuit PDC.

In the pixel P, signal lines DL, GL, PL, RL and SCL for supplying a signal to the pixel driving circuit PDC are disposed.

The data voltage Vdata is supplied to the data line DL, the scan signal SS is supplied to the gate line GL, the driving voltage Vdd for driving the pixel is supplied to the driving power line PL, a reference voltage Vref is supplied to a reference line RL, and a sensing control signal SCS is supplied to a sensing control line SCL.

Referring to FIG. 27, assuming that a gate line of an nth pixel P is “GLn”, a gate line of a (n-1)th pixel P adjacent to the nth pixel P is “GLn-1” and the gate line “GLn-1” of the (n-1)th pixel P serves as a sensing control line SCL of the nth pixel P.

The pixel driving circuit PDC includes, for example, a first thin film transistor TR1 (switching transistor) connected with the gate line GL and the data line DL, a second thin film transistor TR2 (driving transistor) for controlling a magnitude of a current output to the display element 710 in accordance with the data voltage Vdata transmitted through the first thin film transistor TR1 and a third thin film transistor TR3 (reference transistor) for sensing characteristics of the second thin film transistor TR2.

A first capacitor C1 is disposed between a gate electrode G2 of the second thin film transistor TR2 and the display element 710. The first capacitor C1 is referred to as a storage capacitor Cst.

The first thin film transistor TR1 is turned on by a scan signal SS supplied to the gate line GL to transmit the data voltage Vdata, which is supplied to the data line DL, to the gate electrode G2 of the second thin film transistor TR2.

The third thin film transistor TR3 is connected to a first node n1 and the reference line RL between the second thin film transistor TR2 and the display element 710 and thus turned on or off by the sensing control signal SCS and senses characteristics of the second thin film transistor TR2, which is a driving transistor, for a sensing period.

A second node n2 connected with the gate electrode G2 of the second thin film transistor TR2 is connected with the first thin film transistor TR1. The first capacitor C1 is formed between the second node n2 and the first node n1.

When the first thin film transistor TR1 is turned on, the data voltage Vdata supplied through the data line DL is supplied to the gate electrode G2 of the second thin film transistor TR2. The data voltage Vdata is charged in the first capacitor C1 formed between the gate electrode G2 and the source electrode S2 of the second thin film transistor TR2.

When the second thin film transistor TR2 is turned on, the current is supplied to the display element 710 through the second thin film transistor TR2 in accordance with the driving voltage Vdd for driving the pixel, whereby light is output from the display element 710.

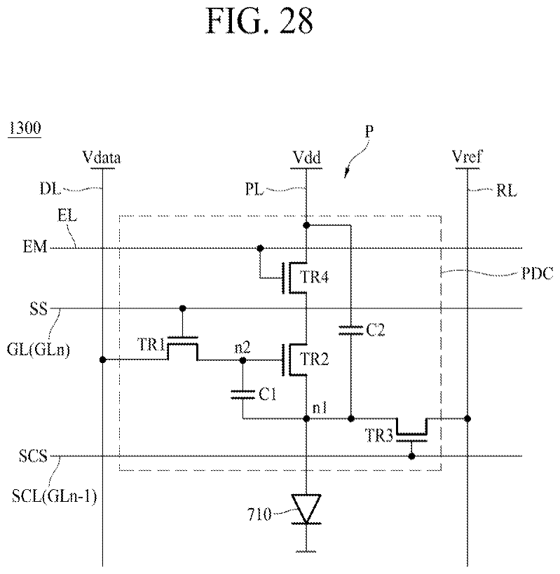

FIG. 28 is a circuit view illustrating any one pixel of a display device 1300 according to further still another aspect of the present disclosure.

The pixel P of the display device 1300 shown in FIG. 28 includes an organic light emitting diode (OLED) that is a display element 710 and a pixel driving circuit PDC for driving the display element 710. The display element 710 is connected with the pixel driving circuit PDC.

The pixel driving circuit PDC includes thin film transistors TR1, TR2, TR3 and TR4.

In the pixel P, signal lines DL, EL, GL, PL, SCL and RL for supplying a driving signal to the pixel driving circuit PDC are disposed.

In comparison with the pixel P of FIG. 27, the pixel P of FIG. 28 further includes a light emission control line EL. An emission control signal EM is supplied to the light emission control line EL.

Also, the pixel driving circuit PDC of FIG. 28 further includes a fourth thin film transistor TR4 that is a light emission control transistor for controlling a light emission timing of the second thin film transistor TR2, in comparison with the pixel driving circuit PDC of FIG. 27.

Referring to FIG. 28, assuming that a gate line of an nth pixel P is “GLn”, a gate line of a (n-1)th pixel P adjacent to the nth pixel P is “GLn-1” and the gate line “GLn-1” of the (n-1)th pixel P serves as a sensing control line SCL of the nth pixel P.

A first capacitor C1 is disposed between a gate electrode G2 of the second thin film transistor TR2 and the display element 710. A second capacitor C2 is disposed between one of terminals of the fourth thin film transistor TR4, to which a driving voltage Vdd is supplied, and one electrode of the display element 710.

The first thin film transistor TR1 is turned on by a scan signal SS supplied to the gate line GL to transmit the data voltage Vdata, which is supplied to the data line DL, to a gate electrode G2 of the second thin film transistor TR2.

The third thin film transistor TR3 is connected to the reference line RL and thus turned on or off by the sensing control signal SCS and senses characteristics of the second thin film transistor TR2, which is a driving transistor, for a sensing period.

The fourth thin film transistor TR4 transfers the driving voltage Vdd to the second thin film transistor TR2 in accordance with the emission control signal EM or shields the driving voltage Vdd. When the fourth thin film transistor is turned on, a current is supplied to the second thin film transistor TR2, whereby light is output from the display element 710.

The pixel driving circuit PDC according to further still another aspect of the present disclosure may be formed in various structures in addition to the above-described structure. The pixel driving circuit PDC may include five or more thin film transistors, for example.

According to the present disclosure, the following advantageous effects may be obtained.

The thin film transistor substrate according to one aspect of the present disclosure includes a second thin film transistor designed to have a large s-factor. Since the second thin film transistor includes a conductive material layer disposed between the substrate and the active layer and connected to the source electrode, the second thin film transistor may have a large s-factor. The second thin film transistor may be used as a driving thin film transistor of the display device, so that the display device may easily express a gray scale.

The thin film transistor substrate according to one aspect of the present disclosure includes a first thin film transistor designed to have a small s-factor and a second thin film transistor designed to have a large s-factor. The first thin film transistor may be used as a switching transistor due to its excellent on-off characteristics, and the second thin film transistor may be used as a driving transistor due to its large s-factor. Therefore, a display device having both excellent switching characteristics and excellent driving characteristics may be manufactured by the thin film transistor substrate according to one aspect of the present disclosure.

The display device according to another aspect of the present disclosure includes a second thin film transistor having a relatively large s-factor, thereby having an excellent gray scale expression capability.

It will be apparent to those skilled in the art that the present disclosure described above is not limited by the above-described aspects and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A thin film transistor substrate comprising:
a substrate;
a first thin film transistor disposed on the substrate; and
a second thin film transistor disposed on the substrate,
wherein the first thin film transistor includes:
a first active layer having a first channel portion;
a first gate insulating layer on the first active layer;
a first gate electrode on the first gate insulating layer;
a first source electrode connected to the first active layer; and
a first drain electrode spaced apart from the first source electrode and connected to the first active layer,
wherein the second thin film transistor includes:
a conductive material layer disposed on the substrate;
a first buffer layer disposed on the conductive material layer;
a second active layer having a second channel portion on the first buffer layer;
a second gate insulating layer disposed on the second active layer;
a second gate electrode disposed on the second gate insulating layer;
a second source electrode connected to the second active layer; and
a second drain electrode spaced apart from the second source electrode and connected to the second active layer,
wherein the conductive material layer is connected to the second source electrode and overlaps with the second channel portion.

2. The thin film transistor substrate of claim 1, wherein the second thin film transistor has an s-factor larger than that of the first thin film transistor.

3. The thin film transistor substrate of claim 1, wherein the conductive material layer has a light shielding characteristic.

4. The thin film transistor substrate of claim 1, wherein the conductive material layer does not overlap with the first channel portion.

5. The thin film transistor substrate of claim 1, wherein the first buffer layer is disposed between the substrate and the first active layer and between the substrate and the second active layer.

6. The thin film transistor substrate of claim 1, wherein the first buffer layer has a thickness of 50 nm to 300 nm.

7. The thin film transistor substrate of claim 1, wherein the second gate insulating layer has a thickness of 0.75 times to 5 times of the first buffer layer.

8. The thin film transistor substrate of claim 1, wherein the first buffer layer includes:
a hydrogen blocking layer disposed on the conductive material layer; and
a buffer insulating layer disposed on the hydrogen blocking layer.

9. The thin film transistor substrate of claim 8, wherein the hydrogen blocking layer includes silicon nitride (SiNx).

10. The thin film transistor substrate of claim 8, wherein the hydrogen blocking layer has a thickness of 10 nm to 100 nm.

11. The thin film transistor substrate of claim 1, wherein the first gate insulating layer and the second gate insulating layer have a same thickness.

12. The thin film transistor substrate of claim 1, wherein the first gate insulating layer and the second gate insulating layer are integrally formed.

13. The thin film transistor substrate of claim 1, wherein at least one of the first gate insulating layer or the second gate insulating layer includes:
a gate insulator; and
an interface layer disposed on the gate insulator,
wherein the interface layer is disposed to be closer to any one of the first channel portion and the second channel portion than the gate insulator.

14. The thin film transistor substrate of claim 13, wherein the interface layer is formed by a metal organic chemical vapor deposition (MOCVD) method.

15. The thin film transistor substrate of claim 13, wherein the interface layer includes at least one of silicon oxide (SiOx), silicon nitride (SiNx) and metal oxide.

16. The thin film transistor substrate of claim 15, wherein the interface layer includes SiO₂.

17. The thin film transistor substrate of claim 13, wherein the interface layer has a thickness of 1 nm to 10 nm.

18. The thin film transistor substrate of claim 1, further comprising a first pad layer disposed between the substrate and the first buffer layer and overlapped with the first channel portion.

19. The thin film transistor substrate of claim 18, wherein the first pad layer does not overlap with the second channel portion.

20. The thin film transistor substrate of claim 18, wherein the first pad layer has conductivity and light shielding characteristics.

21. The thin film transistor substrate of claim 18, wherein the first pad layer is connected to the first gate electrode.

22. The thin film transistor substrate of claim 18, further comprising a second buffer layer disposed between the substrate and the first buffer layer.

23. The thin film transistor substrate of claim 22, wherein the conductive material layer is disposed between the first buffer layer and the second buffer layer.

24. The thin film transistor substrate of claim 22, wherein the first pad layer is disposed between the substrate and the second buffer layer.

25. The thin film transistor substrate of claim 24, wherein the first pad layer is connected to the first source electrode.

26. The thin film transistor substrate of claim 24, wherein the first pad layer is connected to the first gate electrode.

27. The thin film transistor substrate of claim 22, wherein the first pad layer is disposed between the first buffer layer and the second buffer layer.

28. The thin film transistor substrate of claim 27, wherein the first pad layer is connected to the first gate electrode.

29. The thin film transistor substrate of claim 1, wherein at least one of the first active layer or the second active layer includes an oxide semiconductor material.

30. The thin film transistor substrate of claim 29, wherein the oxide semiconductor material includes at least one of IZO (InZnO)-based, IGO (InGaO)-based, ITO (InSnO)-based, IGZO (InGaZnO)-based, IGZTO (InGaZnSnO)-based, GZTO (GaZnSnO)-based, GZO (GaZnO)-based, ITZO (InSnZnO)-based and FIZO (FeInZnO)-based oxide semiconductor material.

31. The thin film transistor substrate of claim 1, wherein at least one of the first active layer or the second active layer includes:
a first oxide semiconductor layer; and
a second oxide semiconductor layer disposed on the first oxide semiconductor layer.

32. The thin film transistor substrate of claim 1, wherein the first thin film transistor is a switching transistor, and the second thin film transistor is a driving transistor.

33. The thin film transistor substrate of claim 7, wherein the second gate insulating layer has a thickness of 1 to 3.5 times of that of the first buffer layer.

34. The thin film transistor substrate of claim 31, wherein at least one of the first active layer or the second active layer further includes a third oxide semiconductor layer disposed on the second oxide semiconductor layer.

35. A display device comprising:
a thin film transistor substrate comprising:
a substrate;
a first thin film transistor disposed on the substrate, wherein the first thin film transistor includes:
a first active layer having a first channel portion;
a first gate insulating layer disposed on the first active layer;
a first gate electrode disposed on the first gate insulating layer;
a first source electrode connected to the first active layer; and
a first drain electrode spaced apart from the first source electrode and connected to the first active layer;
a second thin film transistor disposed on the substrate, wherein the second thin film transistor includes:
a conductive material layer disposed on the substrate;
a first buffer layer disposed on the conductive material layer;
a second active layer having a second channel portion on the first buffer layer;
a second gate insulating layer disposed on the second active layer;
a second gate electrode disposed on the second gate insulating layer;
a second source electrode connected to the second active layer; and
a second drain electrode spaced apart from the second source electrode and connected to the second active layer,
wherein the conductive material layer is connected to the second source electrode and overlaps with the second channel portion; and
a display element connected to the second thin film transistor of the thin film transistor substrate.

36. The display device of claim 35, wherein the display element includes an organic light emitting diode.
